(19) United States
(12) Patent Application Publication
(10) Pub. No.: US 2024/0055352 A1
(43) Pub. Date: Feb. 15, 2024

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Cian-Yu CHEN, Hsinchu (TW); Shin-Yi YANG, Hsinchu (TW); Ching-Fu YEH, Hsinchu (TW); Meng-Pei LU, Hsinchu (TW); Chin-Lung CHUNG, Hsinchu (TW); Yun-Chi CHIANG, Hsinchu (TW); Ming-Han LEE, Hsinchu (TW)

(73) Assignee: Taiwan Semiconductor Manufacturing Company, Ltd., Hsinchu (TW)

(21) Appl. No.: 17/884,817

(22) Filed: Aug. 10, 2022

(51) Int. Cl. H01L 23/532; H01L 23/528; H01L 21/768

(52) U.S. Cl. CPC H01L 23/53238; H01L 23/528; H01L 21/76877; H01L 21/76832; H01L 21/76843

(57) ABSTRACT

A semiconductor device includes a dielectric structure, a conductive structure disposed in the dielectric structure, a first dielectric feature disposed over the dielectric structure, a conductive element disposed in the first dielectric feature and connected to the conductive structure, and a barrier feature disposed around the conductive element and disposed outside of the conductive structure.

### BACKGROUND

Currently, semiconductor devices are widely used in various fields, such as cloud storage, medicine, transportation, mobile devices, etc. The current trend in some aspects of semiconductor device manufacturing focuses on providing semiconductor devices with smaller dimensions and better power efficiency. Therefore, it is desirable to continuously improve the structure and manufacturing of the semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a method for forming a semiconductor device in accordance with some embodiments.

FIGS. 2 to 17 show intermediate steps of a method for forming a semiconductor device in accordance with some embodiments.

FIG. 18 illustrates a method for forming a semiconductor device in accordance with some embodiments.

FIGS. 19 to 54 show intermediate steps of a method for forming a semiconductor device in accordance with some embodiments.

FIG. 55 illustrates a method for forming a semiconductor device in accordance with some embodiments.

FIGS. 56 to 68 show intermediate steps of a method for forming a semiconductor device in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. In addition, the term “source/drain region(s)” may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

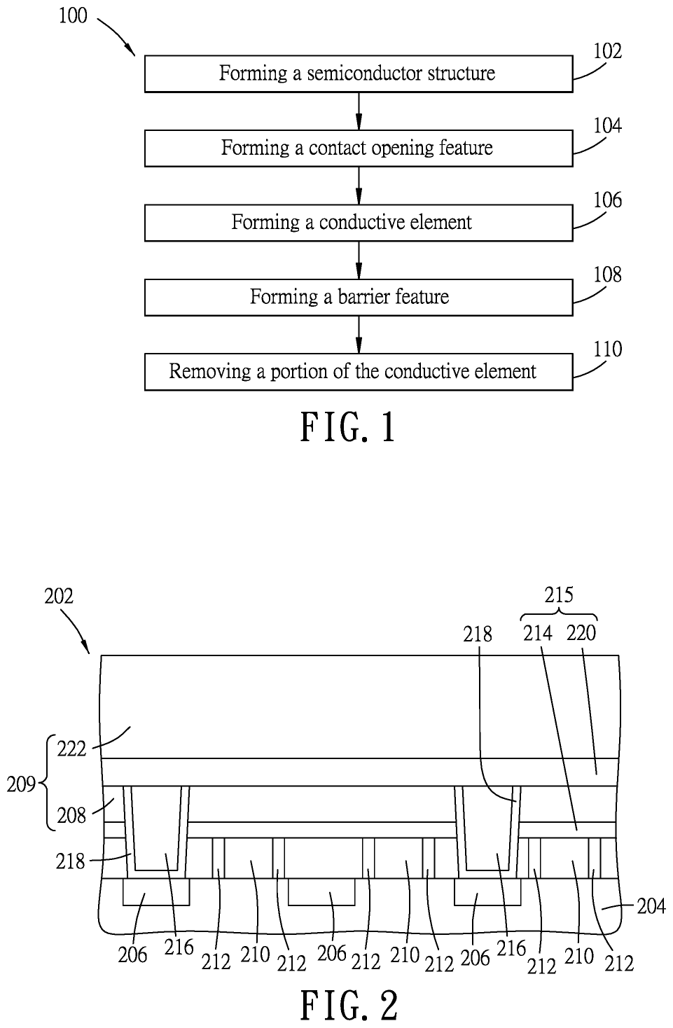

FIG. 1 illustrates a method 100 for forming a semiconductor device 200 (see FIGS. 12 to 14) in accordance with some embodiments. FIGS. 2 to 14 are schematic views showing intermediate stages of the method 100 as depicted in FIG. 1. Additional steps which are not limited to those described in the method 100, can be provided before, during or after forming the semiconductor device 200, and some of the steps described herein may be replaced by other steps or be eliminated. Similarly, additional features may be present, and/or features present may be replaced or eliminated in additional embodiments.

Referring to FIG. 1, in a step 102 of the method 100, a semiconductor structure is formed. Referring to FIG. 2, in some embodiments, the semiconductor structure 202 includes a substrate 204, a plurality of source/drain regions 206 that are disposed in the substrate 204 and that are spaced apart from each other, a first dielectric layer 208 that is disposed over the substrate 204, a plurality of contact structures 216 that are disposed in the first dielectric layer 208 and that are connected to the source/drain regions 206, a plurality of contact liners 218 that respectively surround the contact structures 216, a plurality of gate structures 210 that are disposed among the contact structures 216, a plurality of gate spacers 212 that are disposed adjacent to the gate structures 210, a bottom contact etching stop layer (BCESL) 214 that is disposed in the first dielectric layer 208 and over the gate structures 210, a middle contact etching stop layer (MCESL) 220 that is disposed over the first dielectric layer 208, and a second dielectric layer 222 that is disposed over the MCESL 220. In some embodiments, the first and second dielectric layers 208, 222 may be collectively referred to as a dielectric layer 209. In some embodiments, the BCESL 214 and the MCESL 220 may be collectively referred to as a contact etch stop layer (CESL) 215.

In some embodiments, the substrate 204 may include, for example, but not limited to, an elemental semiconductor or a compound semiconductor. The elemental semiconductor includes a single species of atoms, such as Si or Ge in column XIV of the periodic table, and may be crystalline, polycrystalline, or an amorphous structure. Other suitable materials are within the contemplated scope of the present disclosure. The compound semiconductor includes two or more elements, and examples thereof may include, but are not limited to, silicon carbide (SiC), gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and gallium indium arsenide phosphide (GaInAsP). Other suitable materials are within the contemplated scope of the present disclosure. The compound semiconductor may have a gradient feature in which the composition ratio thereof changes from one location to another location in the compound semiconductor. The compound semiconductor may be formed over a silicon substrate, and the compound semiconductor may be strained. In some embodiments, the substrate 204 may include a multilayer compound semiconductor structure. In some embodiments, the substrate 204 may be a semiconductor-on-insulator (SOI) (e.g., silicon germanium-on-insulator (SGOI)). Generally, an SOI substrate includes a layer of a semiconductor material such as epitaxial silicon, germanium, silicon germanium, or any combination thereof. Other suitable materials are within the contemplated scope of the present disclosure. The SOI substrate may be doped with a P-type dopant, for example, but not limited to, boron (Br), aluminum (Al), or gallium (Ga). Other suitable materials are within the contemplated scope of the present disclosure. Alternatively, the SOI substrate may be doped with an N-type dopant, for example, but not limited to, nitrogen (N), phosphorous (P), or arsenic (As). Other suitable materials are within the contemplated scope of the present disclosure.

In some embodiments, the source/drain regions 206 may be formed by epitaxial growth and/or doping techniques, other suitable techniques, or any combination thereof. In some embodiments, the source/drain regions 206 may be made of crystalline silicon (or other suitable semiconductor materials) doped with P-type dopants, so as to form P-type S/D (source/drain) regions for PMOS (P-type metal oxide semiconductor) transistors. In some embodiments, the P-type dopants may be boron, aluminum, gallium, indium, BF₂, other suitable materials, or any combination thereof. In some embodiments, the source/drain regions 206 may be made of crystalline silicon (or other suitable semiconductor materials) doped with N-type dopants, so as to form N-type S/D regions for NMOS (N-type metal oxide semiconductor) transistors. In some embodiments, the N-type dopants may be phosphorous, nitrogen, arsenic, antimony, other suitable materials, or any combination thereof. In some embodiments, each of the source/drain regions 206 may include one or multiple layers of semiconductor materials.

In some embodiments, each of the first dielectric layer 208 and the second dielectric layer 222 may include a dielectric material, such as oxide-based materials (e.g., SiOₓ, etc.), carbide-based materials (e.g., SiCₓ, SiOₓC_{y}, SiOₓC_{y}H_{z}, etc.), nitride-based materials (e.g., SiNₓ, etc.), other suitable materials, or any combination thereof. In some embodiments, each of the first dielectric layer 208 and the second dielectric layer 222 may be formed by chemical vapor deposition (CVD), physical vapor deposition (PVD), atomic layer deposition (ALD), other suitable techniques, or any combination thereof. In some embodiments, each of the first dielectric layer 208 and the second dielectric layer 222 may have a dielectric constant (e.g., a k-value) ranging from about 1 to about 5, but other ranges of values are also within the scope of this disclosure. In some embodiments, if the k-value is too high, such as higher than about 5, the resulting semiconductor device 200 (see FIGS. 12 to 14) may suffer from RC delay and/or other related issues.

In some embodiments, the contact liners 218 may include a metal material (e.g., Ru, Co, Mo, W, Ni, Ir, Rh, Os, etc.), a nitride-based material (e.g., TiN, TaN, WN, MoN, etc.), other suitable materials, or any combination thereof. In some embodiments, the contact liners 218 may be formed by CVD, ALD, PVD, other suitable techniques, or any combination thereof. In some embodiments, the contact liners 218 may prevent or minimize oxidation of the underlying source/drain regions 206.

In some embodiments, the contact structures 216 may include Mo, W, Ru, Co, Ni, Ir, Rh, Os, other suitable materials, or any combination thereof. In some embodiments, the contact structures 216 may be formed by PVD, plating (including electroplating, electroless plating, etc.), CVD, ALD, other suitable techniques, or any combination thereof. In some embodiments, each of the contact structures 216 may be referred to as MD (metal over diffusion).

In some embodiments, the gate spacers 212 may include silicon oxide, silicon nitride, silicon carbide, silicon oxycarbide, silicon oxynitride, silicon carbonitride, silicon oxycarbonitride, boron nitride, silicon boron nitride, other suitable materials, or any combination thereof. In some embodiments, the gate spacers 212 may be formed by CVD, ALD, PVD, other suitable techniques, or any combination thereof.

In some embodiments, each of the gate structures 210 may include a gate dielectric and a metal gate, where the gate dielectric may include metal oxides (where the metal may include Li, Be, Mg, Ca, Sr, Sc, Y, Zr, Hf, Al, La, Ce, Pr, Nd, Sm, Eu, Gd, Tb, Dy, Ho, Er, Tm, Yb, Lu, other suitable metals, or any combination thereof), metal nitrides, metal silicates, metal oxynitrides, metal aluminates, silicon oxide, silicon nitride, silicon oxynitride, other suitable materials, or any combination thereof, and the metal gate may include polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, other suitable materials, or any combination thereof. In some embodiments, the gate dielectric and the metal gate of each of the gate structures 210 may be formed by CVD, ALD, PVD, other suitable techniques, or any combination thereof.

In some embodiments, each of the BCESL 214 and the MCESL 220 may include metal nitride (e.g., TiN, AlN, etc.), metal oxide (SiOₓ, SiₓO_{y}C_{z}, AlOₓ, etc.), metal carbide (e.g., WC, etc.), other suitable materials, or any combination thereof. In some embodiments, each of the BCESL 214 and the MCESL 220 may be formed by CVD, ALD, PVD, other suitable techniques, or any combination thereof. In some embodiments, each of the BCESL 214 and the MCESL 220 may be single-layered or multi-layered, according to practical requirements.

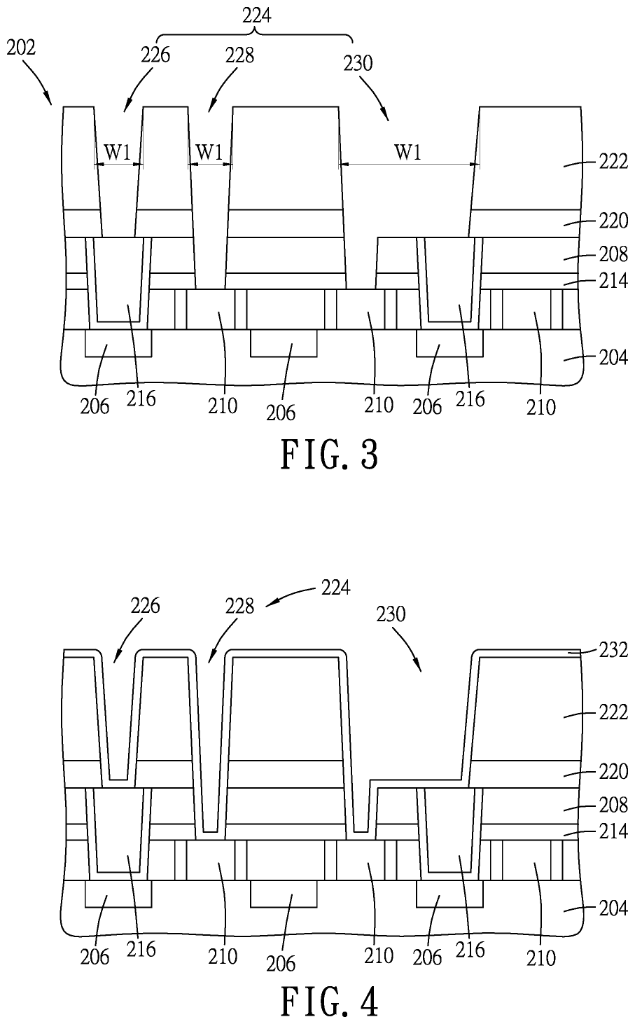

Referring to FIG. 1, in a step 104 of the method 100, a contact opening feature is formed. Referring to FIG. 3, in some embodiments, the contact opening feature 224 may be formed in at least the second dielectric layer 222 of the semiconductor structure 202. In some embodiments, the contact opening feature 224 may be formed further into the first dielectric layer 208 of the semiconductor structure 202. In some embodiments, the contact opening feature 224 may include at least one of a first contact opening 226, a second contact opening 228, or a third contact opening 230. In some embodiments, the first contact opening 226 may penetrate the second dielectric layer 222 and the MCESL 220, and expose a corresponding one of the contact structures 216. In some embodiments, the second contact opening 228 may penetrate the second dielectric layer 222 and the MCESL 220, extend into the first dielectric layer 208, and then penetrate the BCESL 214 to expose a corresponding one of the gate structures 210. In some embodiments, the third contact opening 230 may penetrate the second dielectric layer 222 and the MCESL 220 to expose a corresponding one of the contact structures 216, and may further extend into the first dielectric layer 208 and penetrate the BCESL 214 to expose a corresponding one of the gate structures 210. In some embodiments, the contact opening feature 224 may be formed by dry etch, wet etch, other suitable techniques, or any combination thereof. In some embodiments, each of the first, second, and third contact openings 226, 228, 230 of the contact opening feature 224 may have a circular, oval, square, rectangular top shape, or may have other suitable top shapes. The numbers of the first, second, and third contact openings 226, 228, 230 of the contact opening feature 224 may be changed according to practical requirements. In some embodiments, each of the first, second, and third contact openings 226, 228, 230 of the contact opening feature 224 may have a width (W1) ranging from about 1 nm to about 250 nm, but other ranges of values are also within the scope of this disclosure. In some embodiments, if the width (W1) of each of the first, second, and third contact openings 226, 228, 230 of the contact opening feature 224 is too small, such as smaller than about 1 nm, it may be difficult to fill the contact opening feature 224 in subsequent processes. In some embodiments, if the width (W1) of each of the first, second, and third contact openings 226, 228, 230 of the contact opening feature 224 is too large, such as larger than about 250 nm, the contact opening feature 224 may occupy a large area.

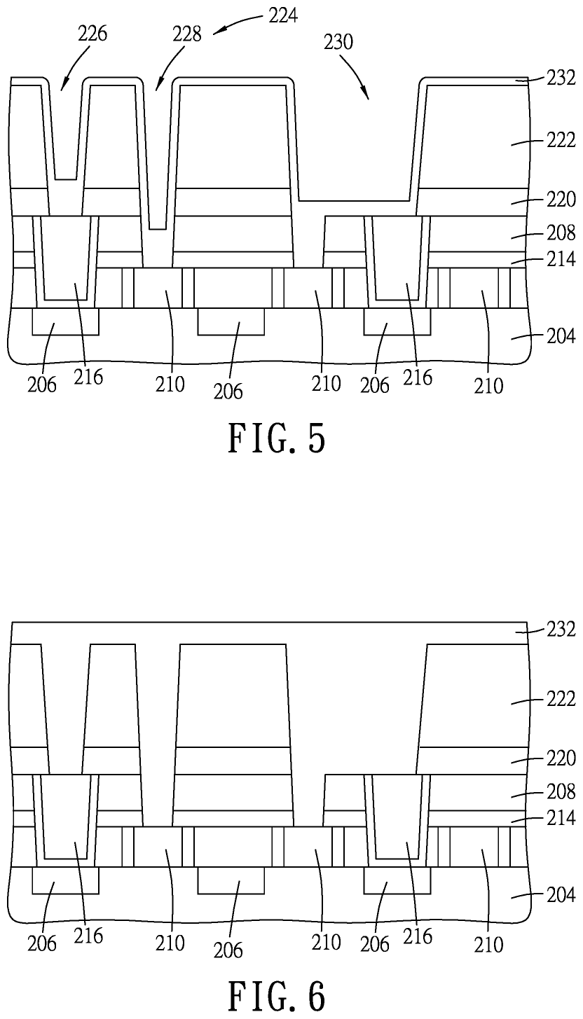

Referring to FIG. 1, in a step 106 of the method 100, a conductive element is formed. Referring to FIGS. 4 to 6, in some embodiments, the conductive element 232 may be formed over the second dielectric layer 222 to partially fill the contact opening feature 224 (see FIGS. 4 and 5) or to completely fill the contact opening feature 224 (see FIG. 6). Referring to FIG. 4, in some embodiments, the conductive element 232 may be conformally formed (e.g., by ALD, CVD, other suitable techniques, or any combination thereof) over the second dielectric layer 222, and on side walls and bottom walls of the first, second, and third contact openings 226, 228, 230 of the contact opening feature 224. In some embodiments, the conductive element 232 may be formed in a non-conformal manner (e.g., by CVD, PVD, other suitable techniques, or any combination thereof). For example, referring to FIG. 5, the conductive element 232 may be formed in such a manner that the thickness of the conductive element 232 on the bottom walls of the first, second, and third contact openings 226, 228, 230 of the contact opening feature 224 is thicker, and the thickness of the conductive element 232 on the side walls of the first, second, and third contact openings 226, 228, 230 of the contact opening feature 224 and over the second dielectric layer 222 is thinner. In some embodiments, the conductive element 232 may be a metal alloy that includes a first metal, and a second metal that may be distributed in the first metal and that is a metal different from the first metal. In some embodiments, the conductive element 232 may be formed by PVD by using a target containing the first metal and the second metal. In some embodiments, conductive element 232 may be formed by CVD and/or ALD by using precursor materials containing the first metal and the second metal. In some embodiments, the first metal may include Cu, Ag, Au, Ni, Co, Fe, Ru, Os, Re, Ir, Pt, Pd, Rh, Al, W, Mo, transition metals, other suitable materials, or any combination thereof. In some embodiments, the second metal may include Al, Mn, Ti, Zr, Hf, Nb, Ta, Mo, W, Zn, V, Cr, Sc, Fe, Y, other suitable materials, or any combination thereof. In some embodiments, the conductive element 232 may be a binary, ternary, quaternary, or more alloy system of the first metal and the second metal. In some embodiments, the conductive element 232 may be a solid solution, an intermetallic compound, a metal alloy with a precipitation phase, other suitable structures, or any combination thereof. In some embodiments, the conductive element 232 may be formed under a temperature ranging from about 25° C. to about 1000° C., but other ranges of values are also within the scope of this disclosure. In some embodiments, if the forming temperature of the conductive element 232 is too high, such as greater than about 1000° C., the semiconductor structure 202 may be negatively affected or even damaged. In some embodiments, when the conductive element 232 is formed by plasma-enhanced techniques, such as plasma-enhanced CVD (PECVD), plasma-enhanced ALD (PEALD), other suitable techniques, or any combination thereof, the power of the plasma may range from about 5000 W to about 50000 W, but other ranges of values are also within the scope of this disclosure. In some embodiments, if the power of the plasma is too low, such as lower than about 5000 W, the plasma may not be generated. In some embodiments, if the power of the plasma is too high, such as greater than about 50000 W, the semiconductor structure 202 may be negatively affected or even damaged.

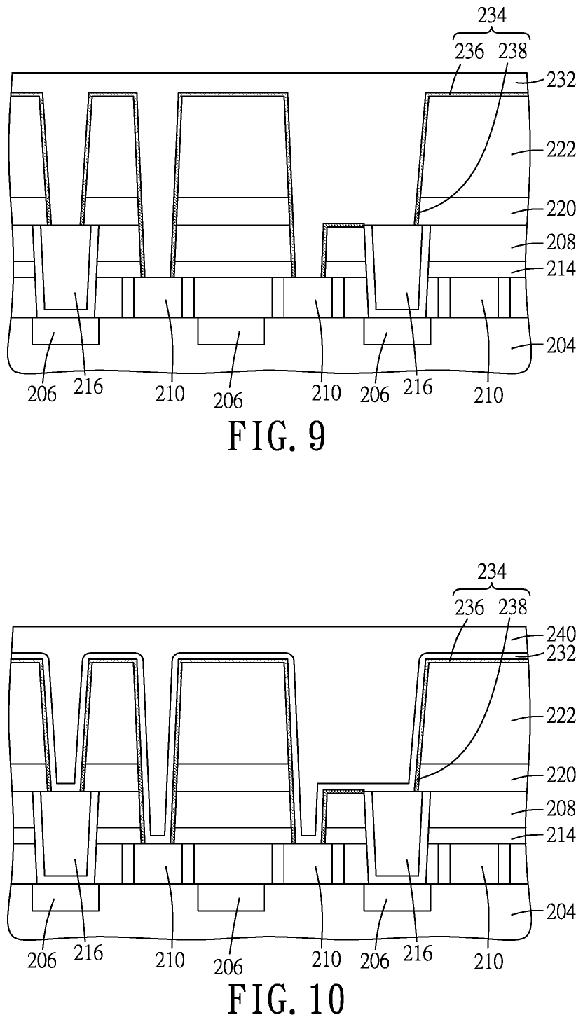

Referring to FIGS. 4, 5, 10, and 11, in some embodiments, if the each of the first, second, and third contact openings 226, 228, 230 of the contact opening feature 224 is partially filled by the conductive element 232, a filling contact material 240 may be formed to fill each of the first, second, and third contact openings 226, 228, 230 of the contact opening feature 224. In some embodiments, the filling contact material 240 may include Cu, Ag, Au, Ni, Co, Fe, Ru, Os, Re, Ir, Pt, Pd, Rh, Al, W, Mo, transition metals, other suitable materials, or any combination thereof, and may be formed by PVD, CVD, ALD, other suitable techniques, or any combination thereof. Referring to FIG. 9, since the first, second and third contact openings 226, 228, 230 of the contact opening feature 224 (see FIG. 3) are fully filled by the conductive element 232, no filling contact material 240 is formed.

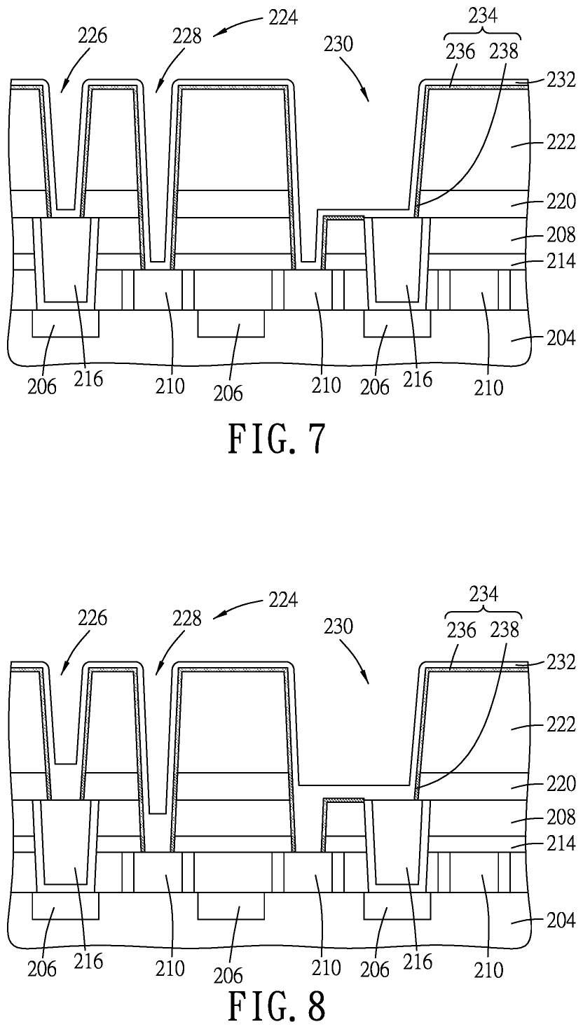

Referring to FIG. 1, in a step 108 of the method 100, a barrier feature is formed. Referring to FIGS. 7 to 9, in some embodiments, the conductive element 232 may react with the dielectric layer 209 (i.e., the first and second dielectric layers 208, 222), and the CESL 215 (i.e., the BCESL 214, and the MCESL 220) to form the barrier feature 234. In some embodiments, if the conductive element 232 is formed at a temperature greater than about 100° C. and/or is formed using a plasma-enhanced technique, the conductive element 232 may react with the dielectric layer 209 and the CESL 215 to form the barrier feature 234. In some embodiments, an annealing process may be conducted to further react the conductive element 232 with the dielectric layer 209 and the CESL 215, under a temperature ranging from about 100° C. to about 1400° C., but other ranges of values are also within the scope of this disclosure. In some embodiments, if the temperature of the annealing process is too low, such as lower than about 100° C., the conductive element 232 may not react further with the dielectric layer 209 and the CESL 215. In some embodiments, if the temperature of the annealing process is too high, such as greater than about 1400° C., the semiconductor structure 202 may be negatively affected or even damaged. In some embodiments, the annealing process may be conducted by rapid thermal annealing (RTA), laser annealing, furnace annealing, other suitable techniques, or any combination thereof. In some embodiments, the second metal in the first metal of the conductive element 232 may react with the dielectric layer 209 and the CESL 215 to form the barrier feature 234. Therefore, the barrier feature 234 may include silicides and/or oxides of the second metal (e.g., Al, Mn, Ti, Zr, Hf, Nb, Ta, Mo, W, Zn, V, Cr, Sc, Fe, Y, other suitable materials, or any combination thereof). In some embodiments, the barrier feature 234 may include a first barrier layer 236 and a second barrier layer 238, where the first barrier layer 236 may be formed as a result of reaction between the conductive element 232 and the dielectric layer 209, and the second barrier layer 238 may be formed as a result of reaction between the conductive element 232 and the CESL 215. In some embodiments, if the proportion of the second metal is too small, there may be insufficient second metal to react with the dielectric layer 209 and the CESL 215 to form the barrier feature 234. In some embodiments, if the proportion of the second metal is too large, the overall resistance of the conductive element 232 may be greater than a desirable value.

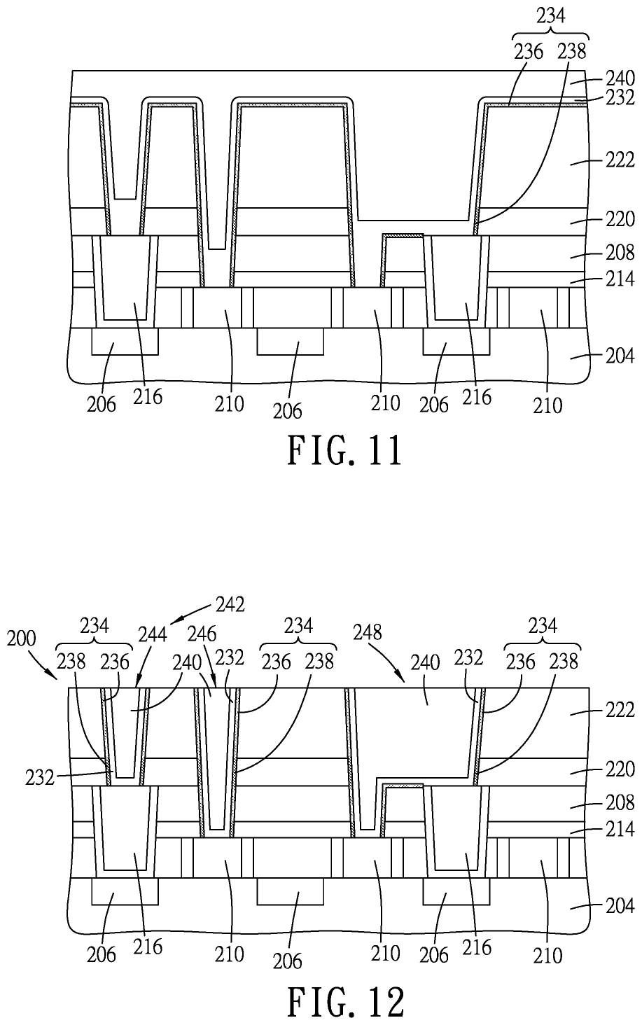

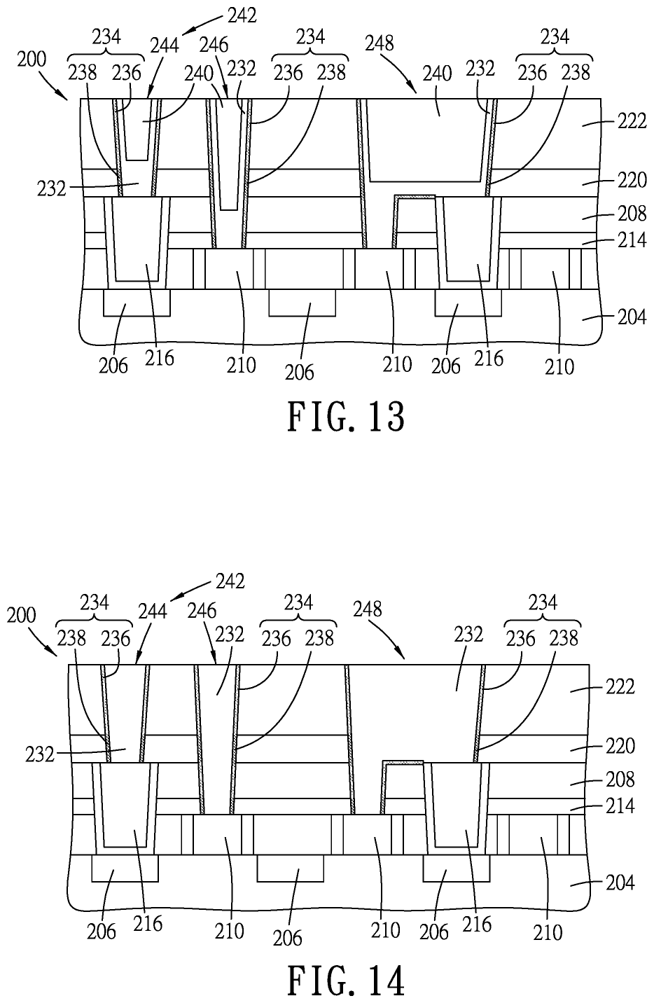

Referring to FIG. 1, in a step 110 of the method 100, a portion of the conductive element is removed to form a contact feature. Referring to FIGS. 10 to 13, in some embodiments, portions of the barrier feature 234, the conductive element 232, and the filling contact material 240 are removed to form the contact feature 242, where the structure of FIG. 12 is obtained from the structure of FIG. 10, and the structure of FIG. 13 is obtained from the structure of FIG. 11. Referring to FIG. 9, top portions of the barrier feature 234 and the conductive element 232 are removed to form the contact feature 242 (see FIG. 14). In some embodiments, the contact feature 242 may include a first contact structure 244, a second contact structure 246, and a third contact structure 248, each of which may include a portion of the conductive element 232 and a portion of the barrier feature 234 (see FIG. 14). Referring to FIGS. 12 and 13, in some embodiments, each of the first contact structure 244, a second contact structure 246, and a third contact structure 248 of the contact feature 242 may further include a portion of the filling contact material 240. In some embodiments, the first contact structure 244 may be connected to a corresponding one of the contact structures 216. In some embodiments, the second contact structure 246 may be connected to a corresponding one of the gate structures 210. In some embodiments, the third contact structure 248 may be connected to a corresponding one of the gate structures 210 and a corresponding one of the contact structures 216. In some embodiments, the removing process may be conducted by chemical mechanical planarization (CMP), dry etch, wet etch, other suitable techniques, or any combination thereof.

In some embodiments, the annealing process may be conducted after the contact material 240 is formed and before the process of removing the conductive element 232 and the filling contact material 240. That is, the barrier feature 234 may be formed after the contact material 240 is formed and before the process of removing the conductive element 232 and the filling contact material 240.

In some embodiments, the annealing process may be conducted after the process of removing the conductive element 232 and the filling contact material 240. That is, the barrier feature 234 may be formed after the process of removing the conductive element 232 and the filling contact material 240.

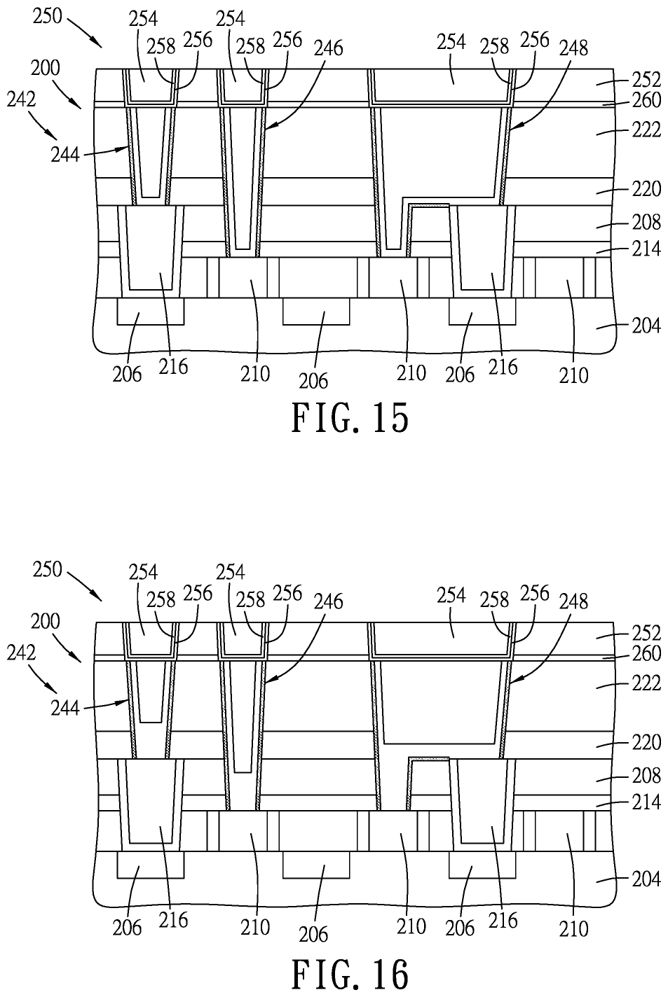

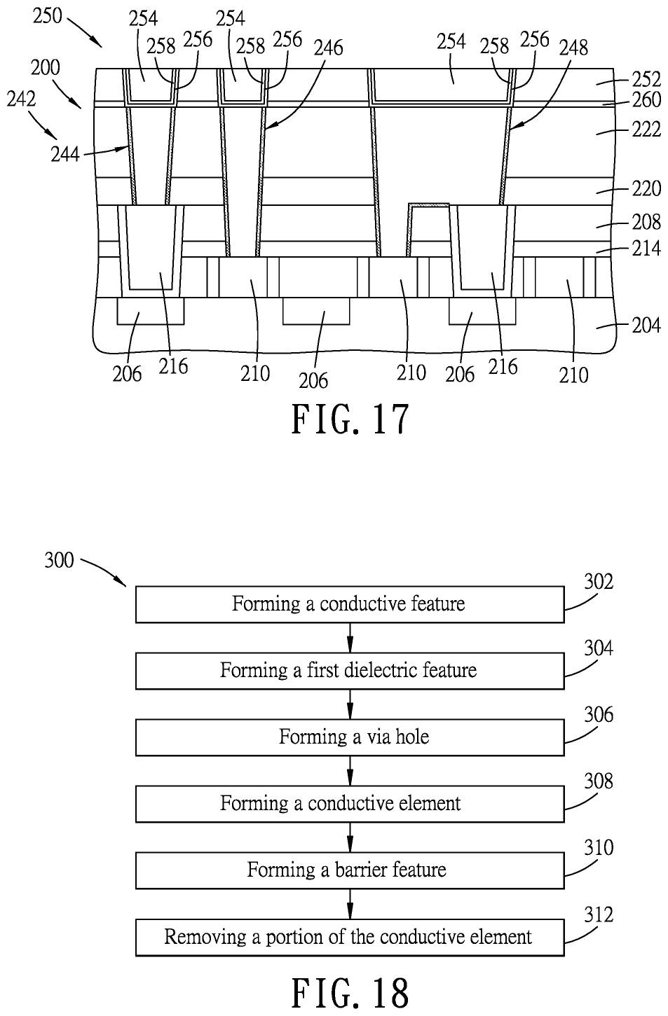

Referring to FIGS. 15 to 17, in some embodiments, the semiconductor device 200 may further include a conductive feature 250 that is disposed over the second dielectric layer 222 of the dielectric layer 209. In some embodiments, the conductive feature 250 includes an etching stop layer (ESL) 260 disposed over the second dielectric layer 222 of the dielectric layer 209, a dielectric structure 252 disposed over the ESL 260, and a plurality of conductive structures 254 that are disposed in the dielectric structure 252 and that are respectively connected to the first, second and third contact structures 244, 246, 248 of the contact feature 242. In some embodiments, the conductive feature 250 may further include a plurality of liner structures 258 that respectively surround the conductive structures 254, and a plurality of barrier structures 256 that respectively surround the liner structures 258. In some embodiments, the ESL 260 may include metal nitride (e.g., TiN, AlN, etc.), metal oxide (SiOₓ, SiₓO_{y}C_{z}, AlOₓ, etc.), metal carbide (e.g., WC, etc.), other suitable materials, or any combination thereof, and may be formed by ALD, CVD, PVD, other suitable techniques, or any combination thereof. In some embodiments, the dielectric structure 252 may include a dielectric material, such as silicon oxide, silicon nitride, silicon oxynitride, amorphous fluorinated carbon, fluorinated silica glass (FSG), carbon doped silicon oxide (e.g., SiCOH), polyimide, parylene, bis-benzocyclobutenes (BCB), other suitable materials, or any combination thereof, and may be made by CVD, ALD, PVD, other suitable techniques, or any combination thereof. In some embodiments, the conductive structures 254 may include Ag, Al, Cu, W, Ni, Ru, other suitable materials, or any combination thereof, and may be made by PVD, plating, other suitable techniques, or any combination thereof. In some embodiments, the barrier structures 256 may include Ti, Ta, TiN, TaN, other suitable materials, or any combination thereof, and may be made by ALD, CVD, PVD, other suitable techniques, or any combination thereof. In some embodiments, the liner structures 258 may include Co, Ru, other suitable materials, or any combination thereof, and may be made by ALD, CVD, PVD, other suitable techniques, or any combination thereof. In some embodiments, the conductive structures 254 of the conductive feature 250 may be formed by a damascene process, a direct etching process, or other suitable techniques.

Referring to FIGS. 12 to 14, in some embodiments, the barrier feature 234 may have a thickness ranging from about 0.1 nm to about 10 nm, but other ranges of values are also within the scope of this disclosure. In some embodiments, if the thickness of the barrier feature 234 is too small, such as smaller than about 0.1 nm, the barrier feature 234 may not be able to block outward-diffusion of the contact feature 242. In some embodiments, if the thickness of the barrier feature 234 is too large, such as larger than about 10 nm, the resistance of the barrier feature 234 may be too high.

In some embodiments, before forming the conductive feature 250, each of the first, second, and third contact structures 244, 246, 248 of the contact feature 242 may be covered by a metal cap (not shown), which may be formed by selective ALD, CVD, electroless deposition (ELD), other suitable techniques, or any combination thereof.

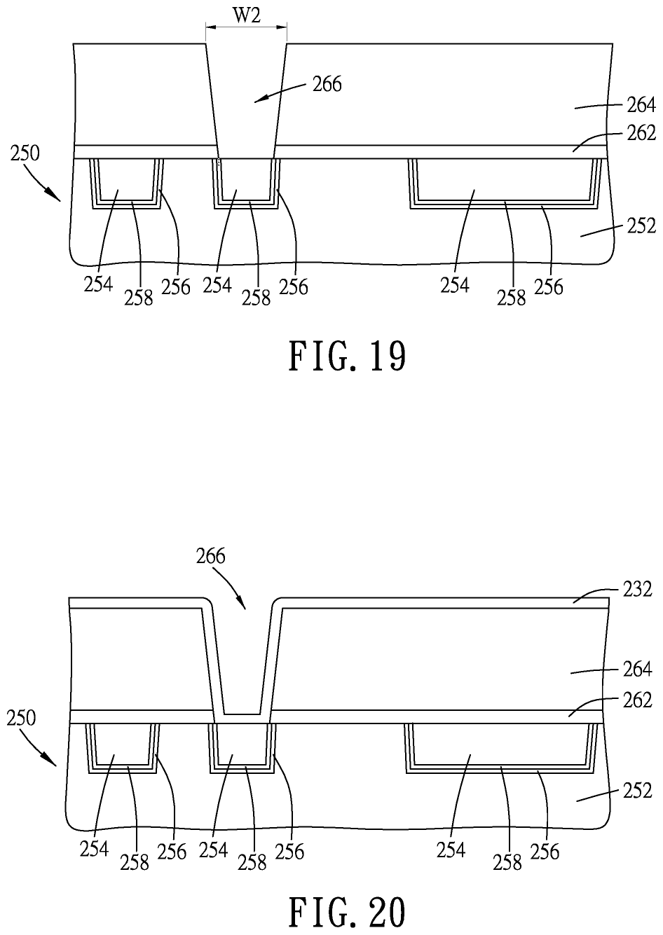

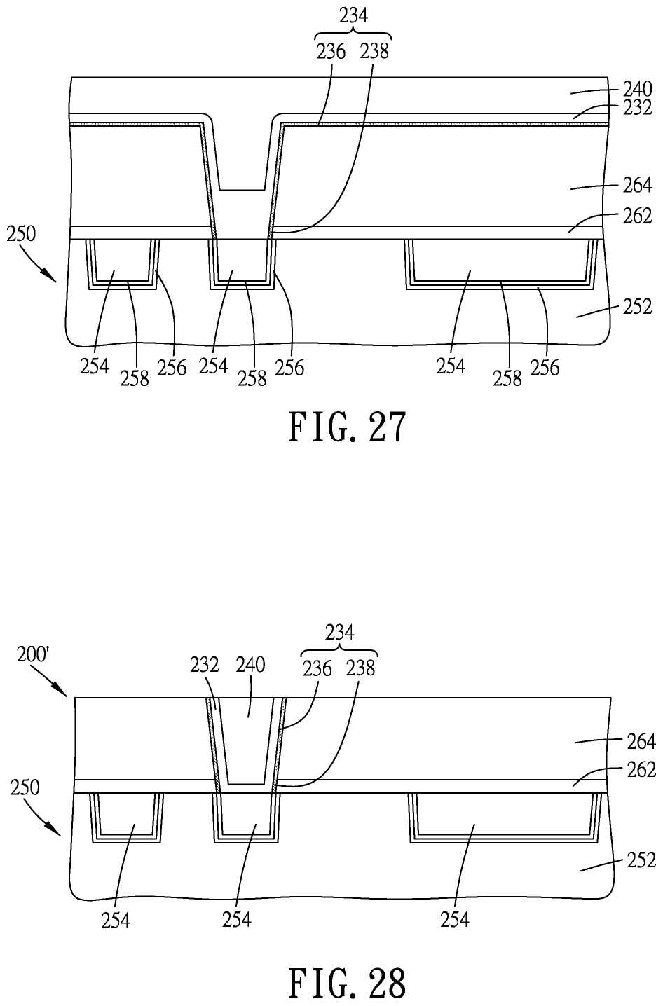

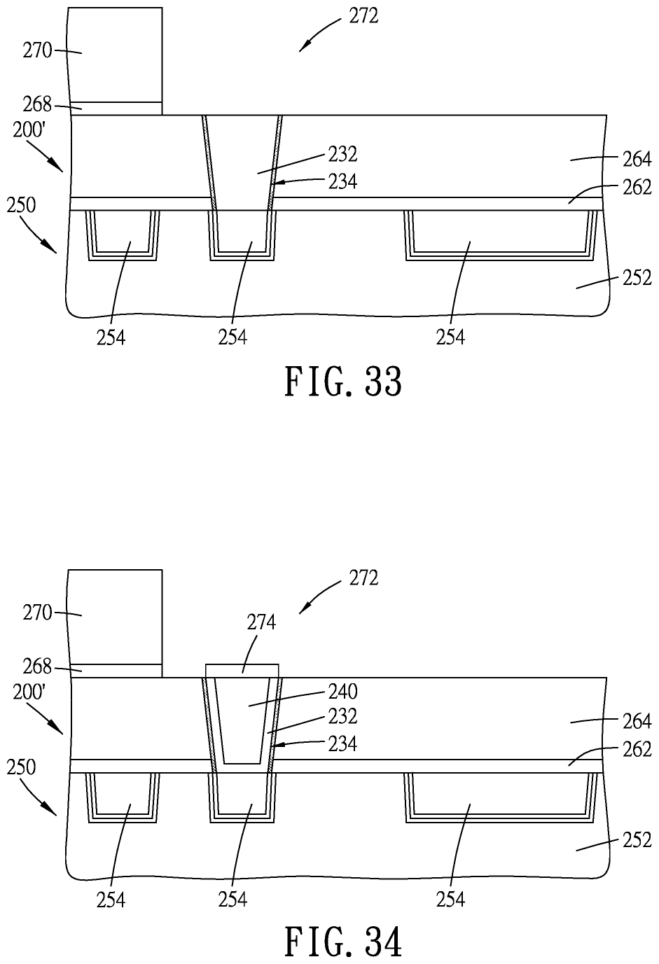

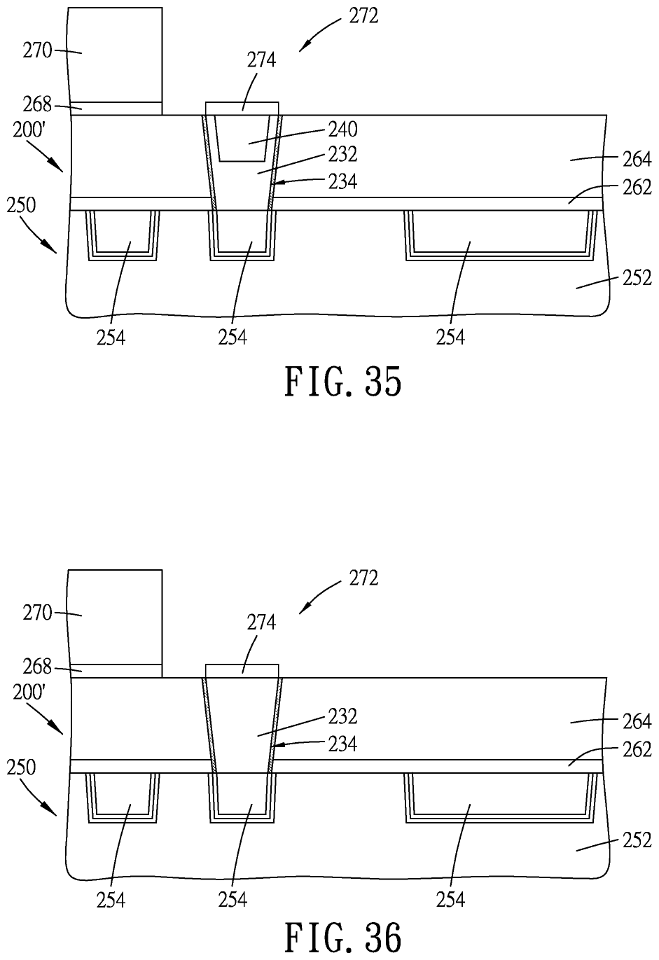

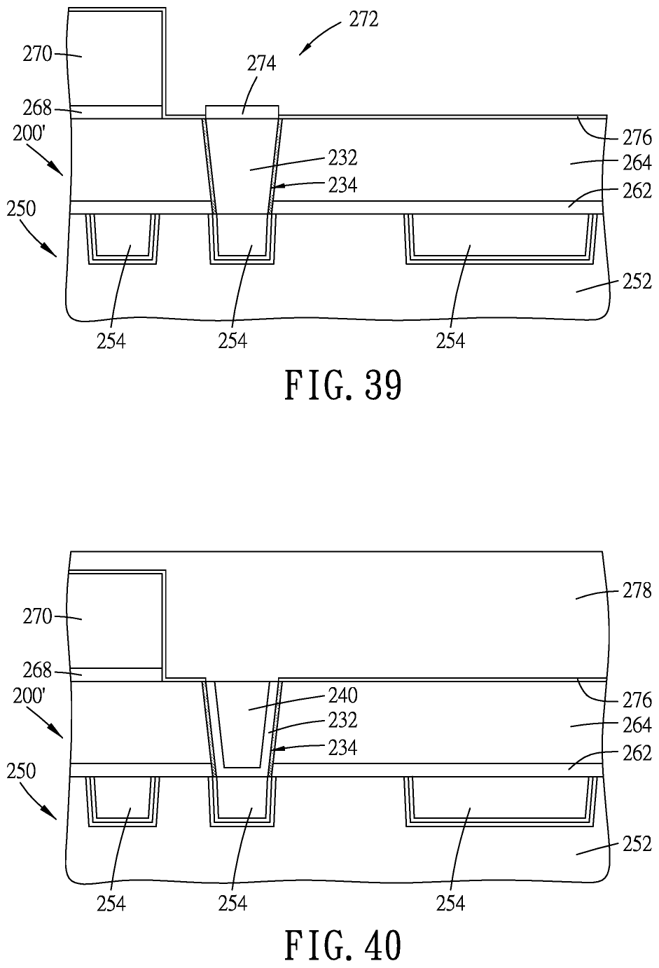

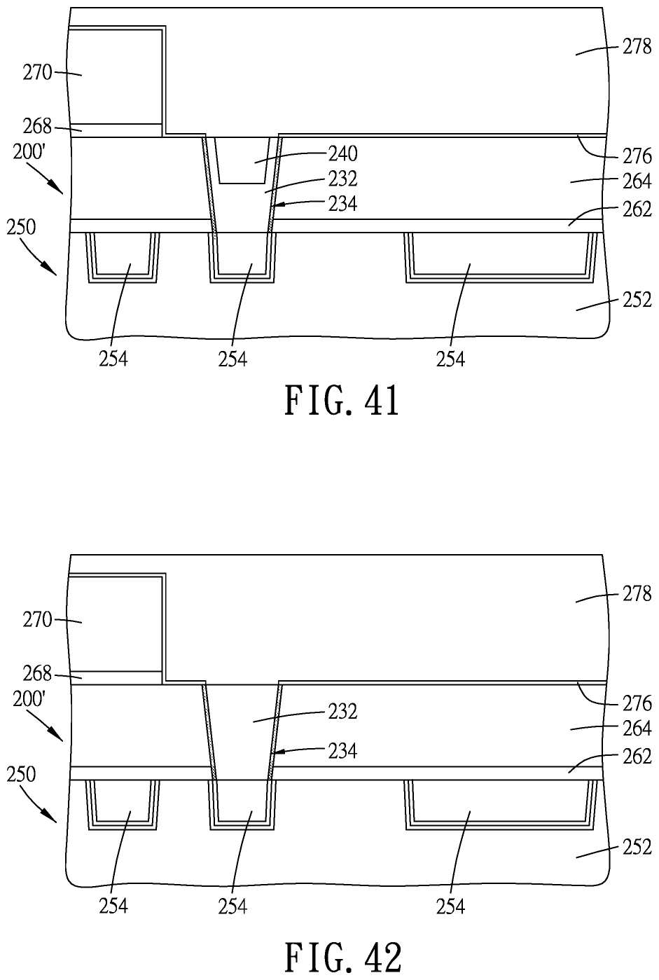

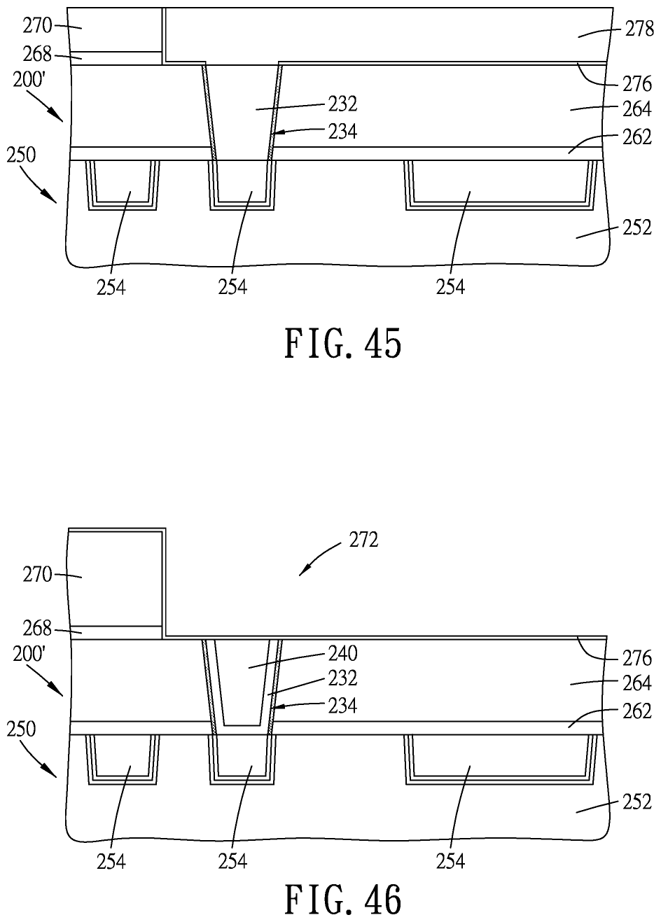

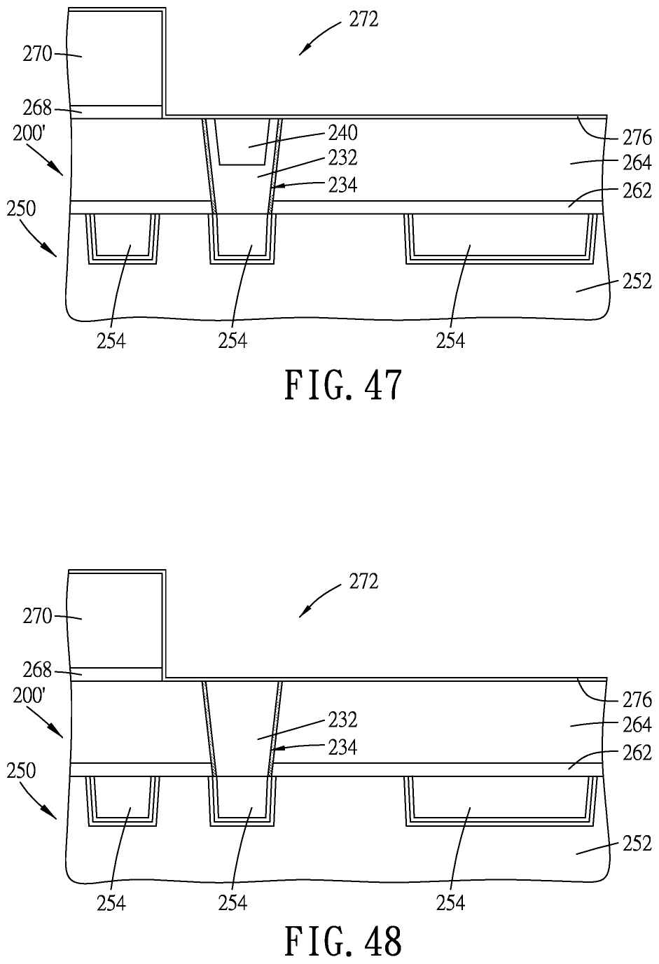

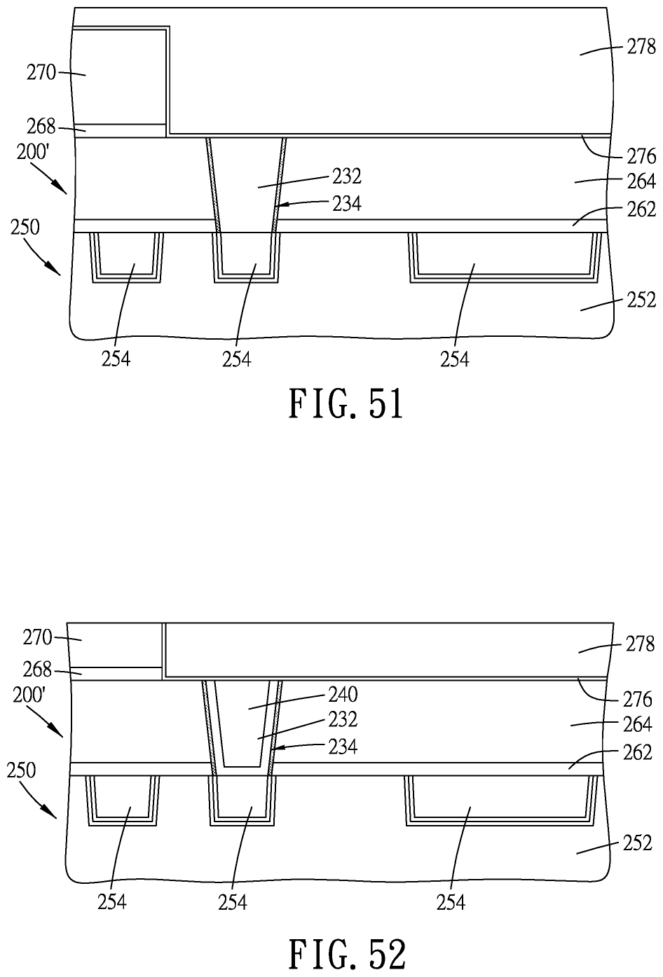

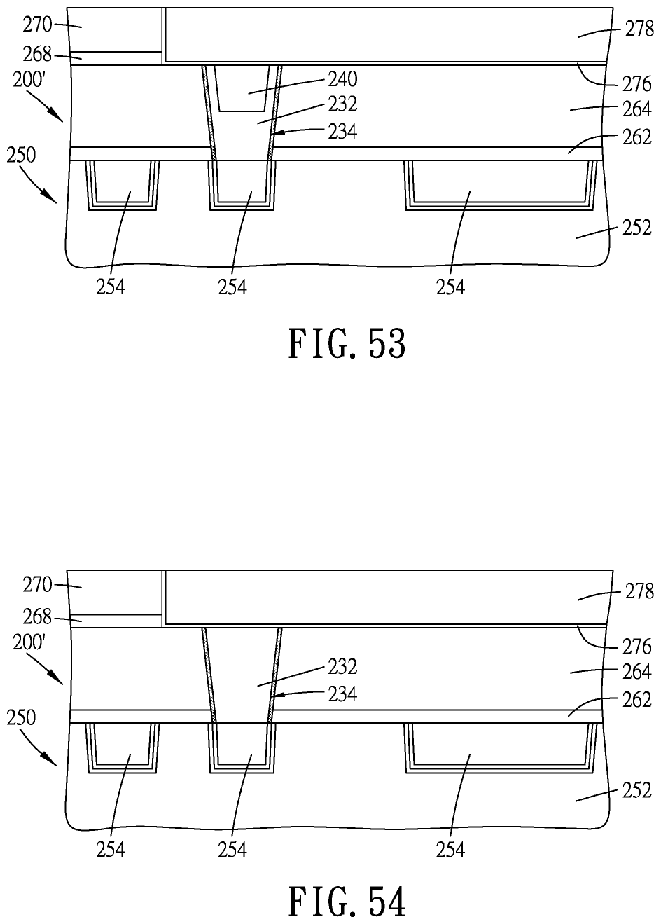

FIG. 18 illustrates a method 300 for forming a semiconductor device 200′ (see FIGS. 28 to 30) in accordance with some embodiments. FIGS. 19 to 54 are schematic views showing intermediate stages of the method 300 as depicted in FIG. 18. Additional steps which are not limited to those described in the method 300, can be provided before, after or during forming the semiconductor device 200′, and some of the steps described herein may be replaced by other steps or be eliminated. Similarly, additional features may be present, and/or features present may be replaced or eliminated in additional embodiments.

Referring to FIG. 18, in a step 302 of the method 300, the conductive feature is formed. Referring to FIG. 19, in some embodiments, the conductive feature 250 may include a structure the same or similar to the structure of the conductive feature 250 shown in FIGS. 15 to 17 with any necessary changes made to the conductive feature 250 in FIG. 19. In some embodiments, the structure below the conductive feature 250 in FIGS. 15 to 17 may be applied to the conductive feature 250 (e.g., may be disposed below the conductive feature 250), but is not shown in FIG. 19 and subsequent steps for the sake of brevity.

Referring to FIG. 18, in a step 304 of the method 300, a first dielectric feature is formed. Referring to FIG. 19, in some embodiments, the first dielectric feature 264 is formed over the conductive feature 250. In some embodiments, prior to forming the first dielectric feature 264, a first etching stop layer (ESL) 262 may be formed over the conductive feature 250. In some embodiments, the first ESL 262 may include metal nitride (e.g., TiN, AlN, etc.), metal oxide (SiOₓ, SiₓO_{y}C_{z}, AlOₓ, etc.), metal carbide (e.g., WC, etc.), other suitable materials, or any combination thereof, and may be formed by ALD, CVD, PVD, other suitable techniques, or any combination thereof. In some embodiments, the first dielectric feature 264 may include a dielectric material, such as silicon oxide, silicon nitride, silicon oxynitride, amorphous fluorinated carbon, FSG, carbon doped silicon oxide (e.g., SiCOH), polyimide, parylene, BCB, other suitable materials, or any combination thereof, and may be made by CVD, ALD, PVD, other suitable techniques, or any combination thereof.

Referring to FIG. 18, in a step 306 of the method 300, a via hole is formed. Referring to FIG. 19, in some embodiments, the via hole 266 is formed in the first dielectric feature 264, and penetrates the first dielectric feature 264 and the first ESL 262 to expose a corresponding one of the conductive structures 254. In some embodiments, the via hole 266 may be formed by dry etching (e.g., plasma dry etching), other suitable techniques, or any combination thereof. In some embodiments, the via hole 266 may have a circular, oval, square, or rectangular shape, or other suitable shapes, when viewed from above. In some embodiments, the via hole 266 may have a width (W2) ranging from about 1 nm to about 250 nm, but other ranges of values are also within the scope of this disclosure. In some embodiments, if the width (W2) of the via hole 266 is too small, such as smaller than about 1 nm, it may be difficult to fill the via hole 266 in subsequent processes. In some embodiments, if the width (W2) of the via hole 266 is too large, such as larger than about 250 nm, the via hole 266 may occupy a large area.

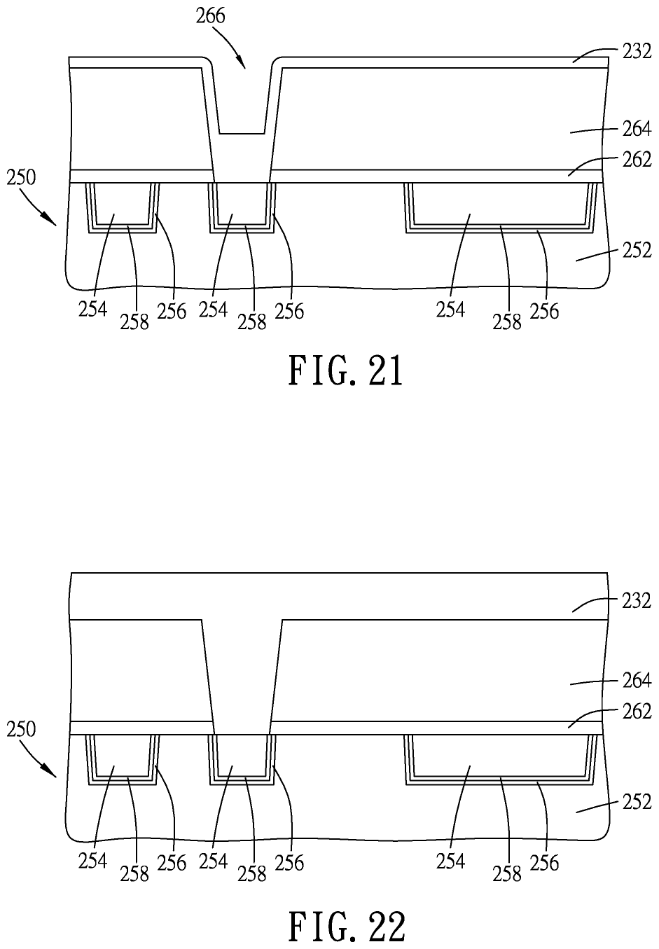

Referring to FIG. 18, in a step 308 of the method 300, the conductive element is formed. Referring to FIGS. 20 to 22, in some embodiments, the conductive element 232 as illustrated in FIGS. 4 to 6 and the related description above is formed over the first dielectric feature 264 and in the via hole 266. Referring to FIG. 20, in some embodiments, the conductive element 232 may be formed in a conformal manner (e.g., by ALD, CVD, other suitable techniques, or any combination thereof) on the first dielectric feature 264 and partially filling the via hole 266. Referring to FIG. 21, in some embodiments, the conductive element 232 may be formed in a non-conformal manner (e.g., by CVD, PVD, other suitable techniques, or any combination thereof) on the first dielectric feature 264 and partially filling the via hole 266, where the thickness of the conductive element 232 on the bottom wall of the via hole 266 is thicker, and the thickness of the conductive element 232 on the side wall of the via hole 266 and over the first dielectric feature 264 is thinner. Referring to FIG. 22, in some embodiments, the conductive element 232 may be formed to completely fill the via hole 266 (see FIG. 19) and cover over the first dielectric feature 264.

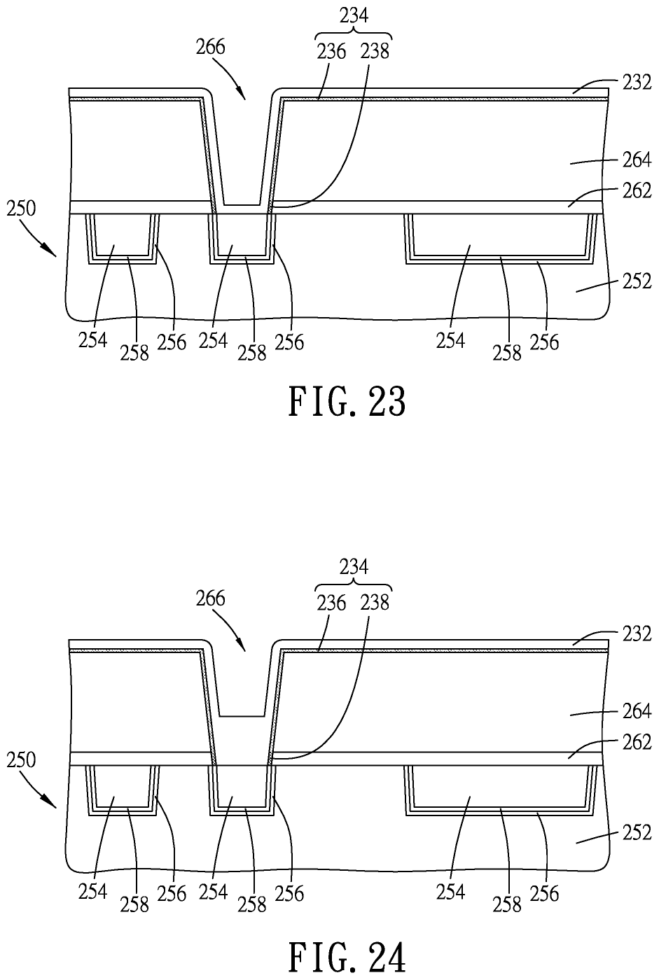

Referring to FIG. 18, in a step 310 of the method 300, the barrier feature is formed. Referring to FIGS. 23 to 25, in some embodiments, the barrier feature 234 is formed by reaction between the conductive element 232 and the first dielectric feature 264 and the first ESL 262, where the formation mechanism of the barrier feature 234 shown in FIGS. 23 to 25 are similar to the formation mechanism of the barrier feature 234 shown in FIGS. 7 to 9, and are therefore not repeated for the sake of brevity. In some embodiments, the barrier feature 234 includes the first barrier layer 236 as a result of reaction between the conductive element 232 and the first dielectric feature 264, and the second barrier layer 238 as a result of reaction between the conductive element 232 and the first ESL 262.

Referring to FIGS. 23, 24, 26, and 27, in some embodiments, the filling contact material 240 may be formed over the conductive element 232 and fill the via hole 266.

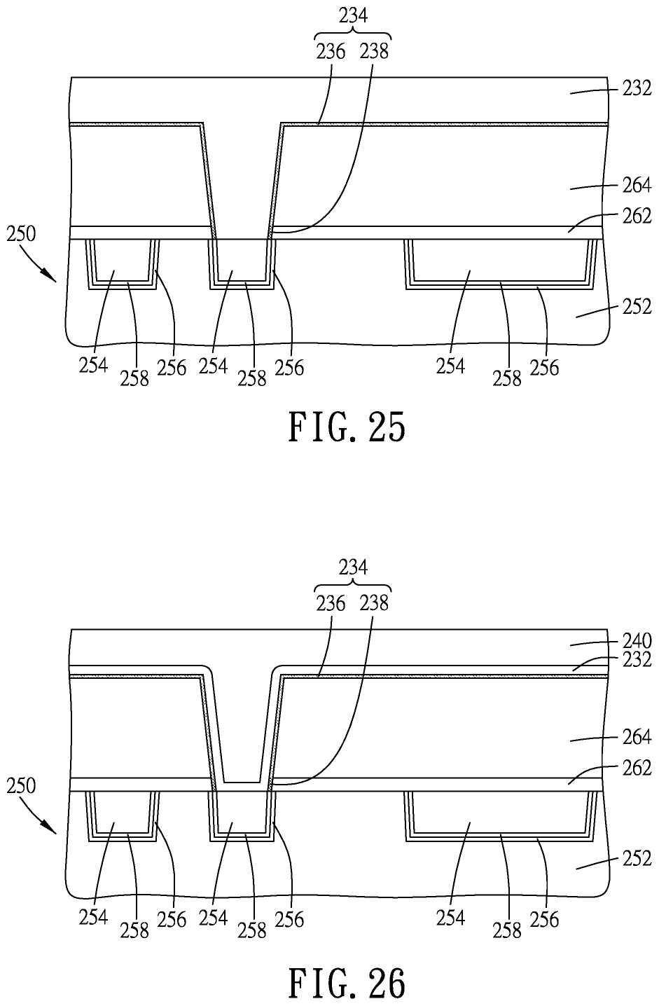

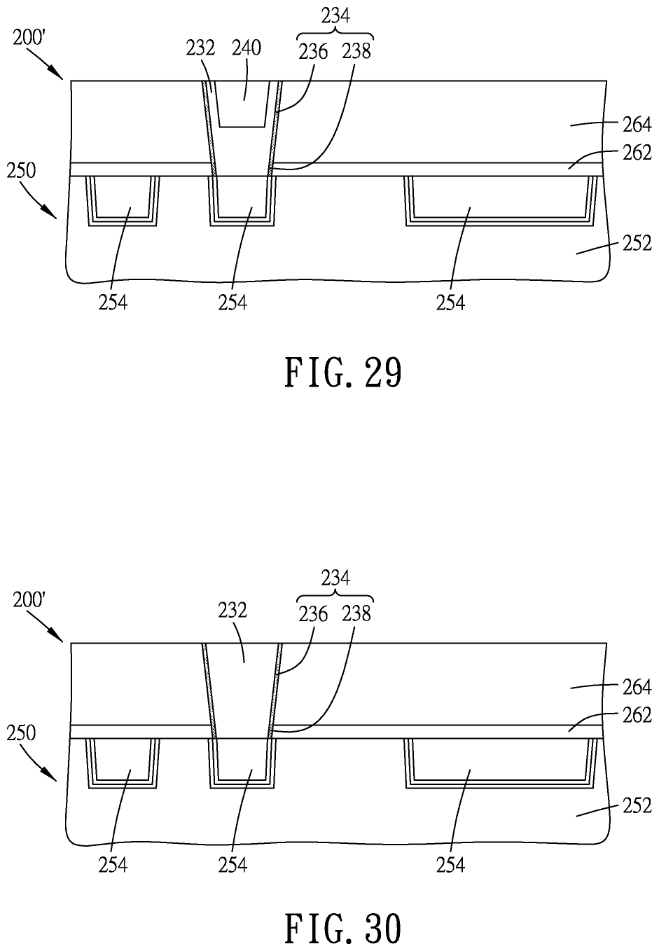

Referring to FIG. 18, in a step 312 of the method 300, a portion of the conductive element is removed. Referring to FIGS. 25 to 30, in some embodiments, portions of the conductive element 232, the barrier feature 234, and the filling contact material 240 may be removed, so that the via hole 266 (see FIG. 19) is filled with a portion of the filling contact material 240, a portion of the conductive element 232 surrounding the filling contact material 240, and a portion of the barrier feature 234 surrounding the conductive element 232 (see FIGS. 28 and 29), or is filled with a portion of the conductive element 232 and a portion of the barrier feature 234 surrounding the conductive element 232 (see FIG. 30), thereby obtaining the semiconductor device 200′.

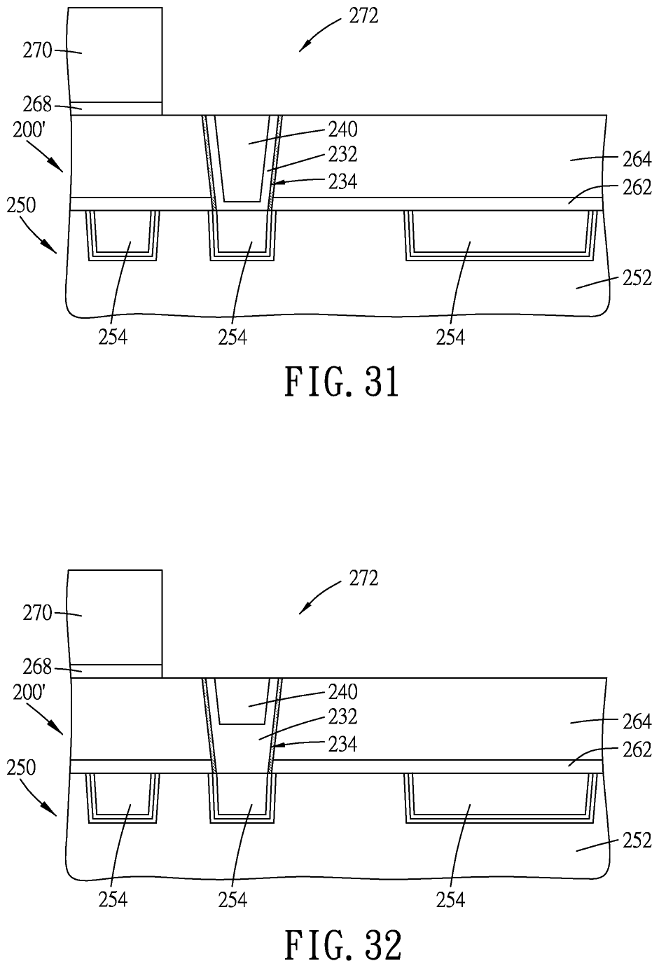

Referring to FIGS. 31 to 33, in some embodiments, a second etching stop layer (ESL) 268 may be formed over the first dielectric feature 264, and a second dielectric feature 270 may be formed over the second ESL 268, followed by forming a trench 272 in the second dielectric feature 270, where the trench 272 penetrates the second dielectric feature 270 and the second ESL 268 and exposes the conductive element 232 and the filling contact material 240. In some embodiments, the second ESL 268 may include nitride (e.g., TiN, AlN, etc.), metal oxide (SiOₓ, SiₓO_{y}C_{z}, AlOₓ, etc.), metal carbide (e.g., WC, etc.), other suitable materials, or any combination thereof, and may be formed by ALD, CVD, PVD, other suitable techniques, or any combination thereof. In some embodiments, the second dielectric feature 270 may include a dielectric material, such as silicon oxide, silicon nitride, silicon oxynitride, amorphous fluorinated carbon, FSG, carbon doped silicon oxide (e.g., SiCOH), polyimide, parylene, BCB, other suitable materials, or any combination thereof, and may be made by CVD, ALD, PVD, other suitable techniques, or any combination thereof. In some embodiments, the second dielectric feature 270 may include a dielectric material, such as silicon oxide, silicon nitride, silicon oxynitride, amorphous fluorinated carbon, FSG, carbon doped silicon oxide (e.g., SiCOH), polyimide, parylene, BCB, other suitable materials, or any combination thereof, and may be made by CVD, ALD, PVD, other suitable techniques, or any combination thereof. In some embodiments, the trench 272 may be formed by dry etching (e.g., plasma dry etching), other suitable techniques, or any combination thereof.

Referring to FIGS. 34 to 36, in some embodiments, a blocking layer 274 may be selectively formed to cover the filling contact material 240 and the conductive element 232 and may be formed outside of the first dielectric feature 264. In some embodiments, the blocking layer may include a plurality of self-assembled monolayer (SAM) molecules each including a head group that can be selectively bonded to the filling contact material 240 and the conductive element 232, a functional group, and a tail that is connected between the head group and the functional group. In some embodiments, the head groups of the SAM molecules may contain phosphorus (P), sulfur (S), nitrogen (N), oxygen (O), other suitable materials, or any combination thereof. Examples of SAM may include alkanethiol, dialkyl disulfide, dialkyl sulfide, carboxylic acid, nitrile, etc.

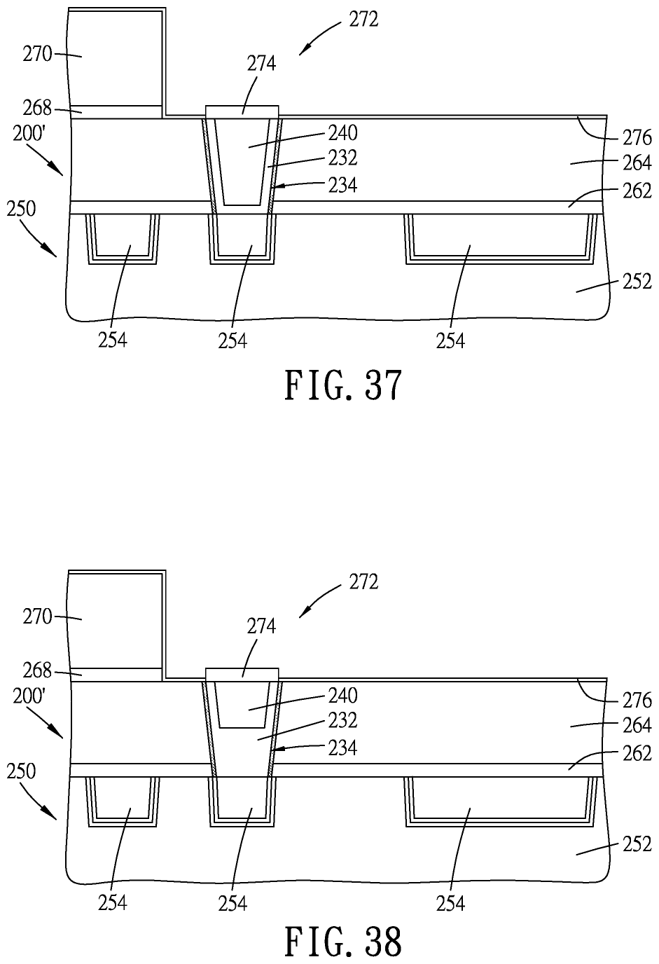

Referring to FIGS. 37 to 39, in some embodiments, a barrier element 276 may be selectively formed over the first dielectric feature 264 and the second dielectric feature 270, and may be formed outside of the blocking layer 274. In some embodiments, the barrier element 276 may be formed by ALD, CVD, PVD, other suitable techniques, or any combination thereof. In some embodiments, the functional groups of the SAM molecules may be hydrophobic to repulse a precursor for forming the barrier element 276, and the barrier element 276 is therefore formed outside of the blocking layer 274. In some embodiments, the functional groups may have low reactivity to the precursor for forming the barrier element 276. Examples of the functional groups may be alkyl group, benzyl group, etc. In some embodiments, the barrier element 276 may include TiN, TaN, Ru, Co, W, Mo, other suitable materials, or any combination thereof.

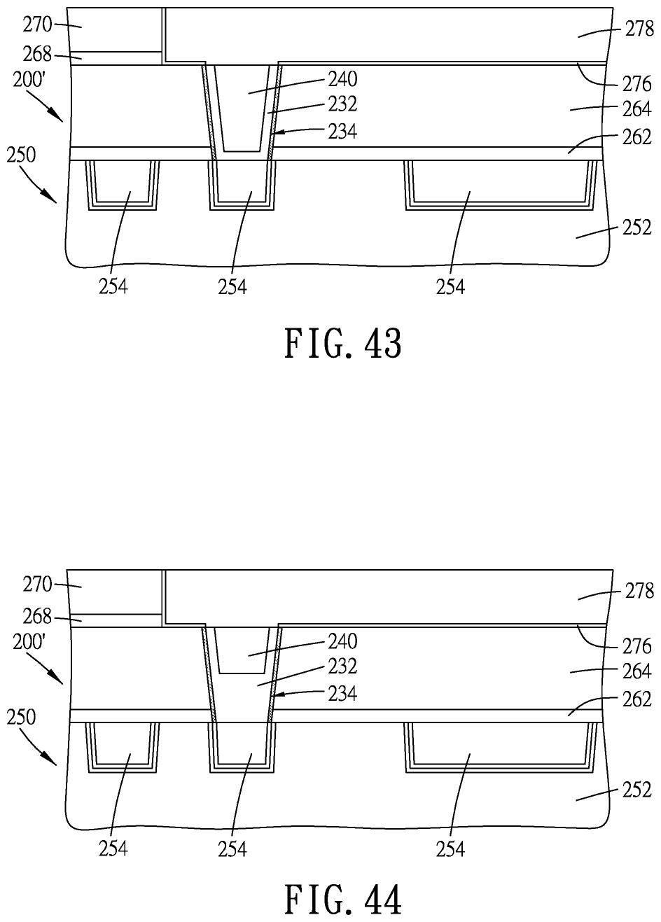

Referring to FIGS. 40 to 42, in some embodiments, the blocking layer 274 (see FIGS. 37 to 39) is removed. In some embodiments, the blocking layer 274 may be removed by plasma dry etching, chemical wet etching (e.g., using high temperature sulfuric acid and hydrogen peroxide mixture (SPM), SC1 solution (NH₄OH/H₂O₂/H₂O), SC2 solution (HCl//H₂O₂/H₂O), diluted HF, diluted HCl, diluted NH₄OH, diluted H₂O₂, H₃PO₄, etc.), ashing, other suitable techniques, or any combination thereof. Then, in some embodiments, a conductive layer 278 may be formed over the second dielectric feature 270 and the barrier element 276, and fill the trench 272 (see FIGS. 37 to 39). In some embodiments, the conductive layer 278 may include Cu, Co, Ru, other suitable materials, or any combination thereof, and may be made by PVD, plating, other suitable techniques, or any combination thereof. Then, referring to FIGS. 43 to 45, in some embodiments, portions of the conductive layer 278 and the barrier element 276 may be removed, leaving the conductive layer 278 completely filling the trench 272 (see FIGS. 37 to 39), where the barrier element 276 surrounds the conductive layer 278 and is disposed outside of the conductive element 232 and the filling contact material 240.

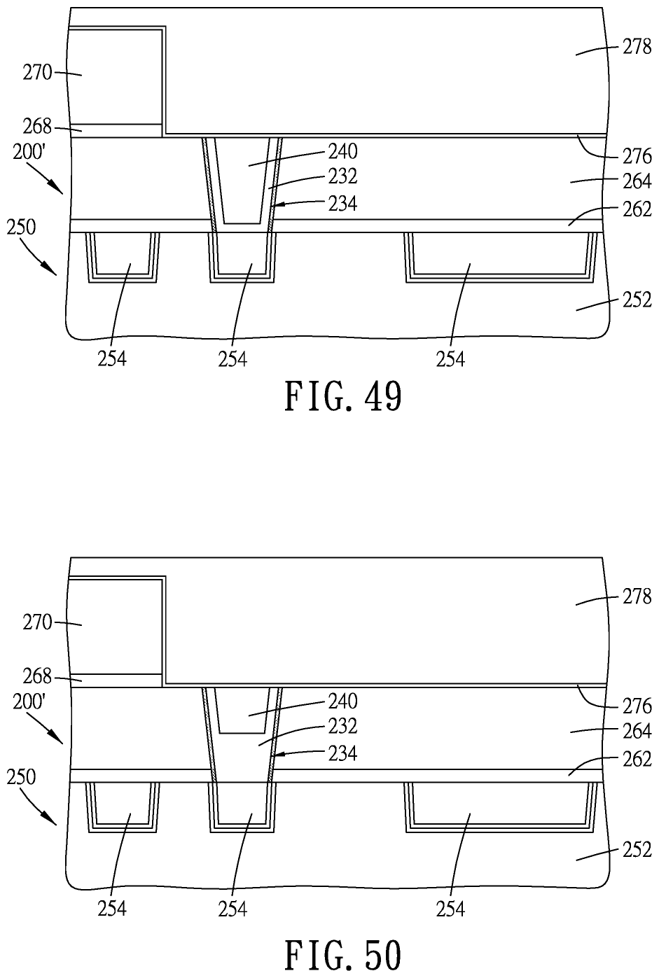

Referring to FIGS. 31 to 33 and 46 to 48, in some embodiments after the formation of the trench 272, the barrier element 276 may be formed over the first and second dielectric features 264, 270 and over the conductive element 232 and the filling contact material 240, where the blocking layer 274 (see FIGS. 34 to 36) is not formed. Then, referring to FIGS. 49 to 51, the conductive layer 278 is formed over the barrier element 276 and fills the trench 272. Afterwards, referring further to FIGS. 52 to 54, portions of the conductive layer 278 and the barrier element 276 are removed, leaving the conductive layer 278 filling the trench 272, and leaving the barrier element 276 surrounding the conductive layer 278 and covering the conductive element 232 and the filling contact material 240.

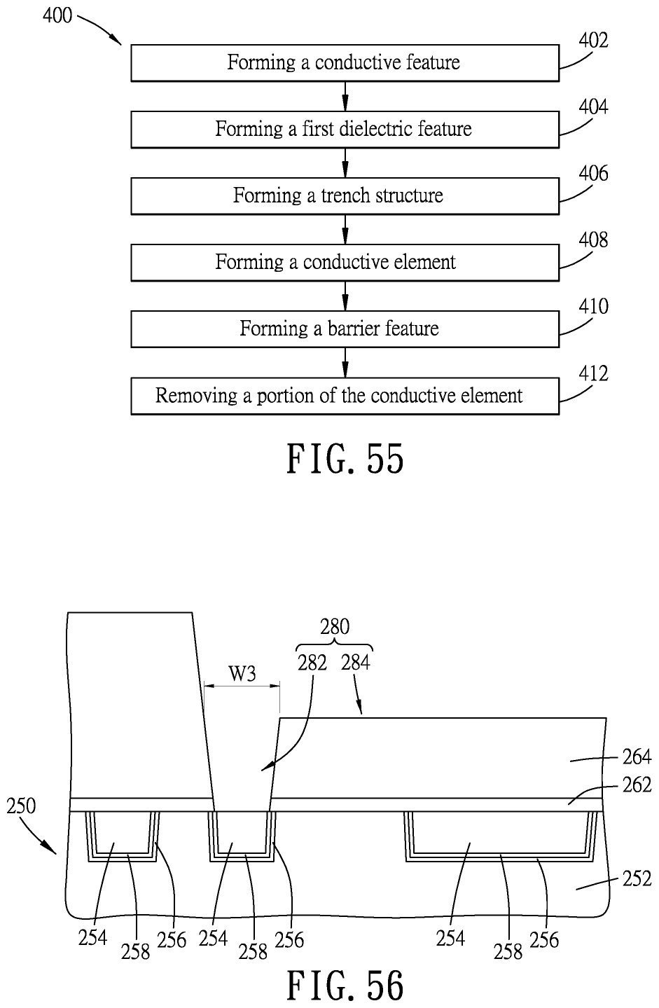

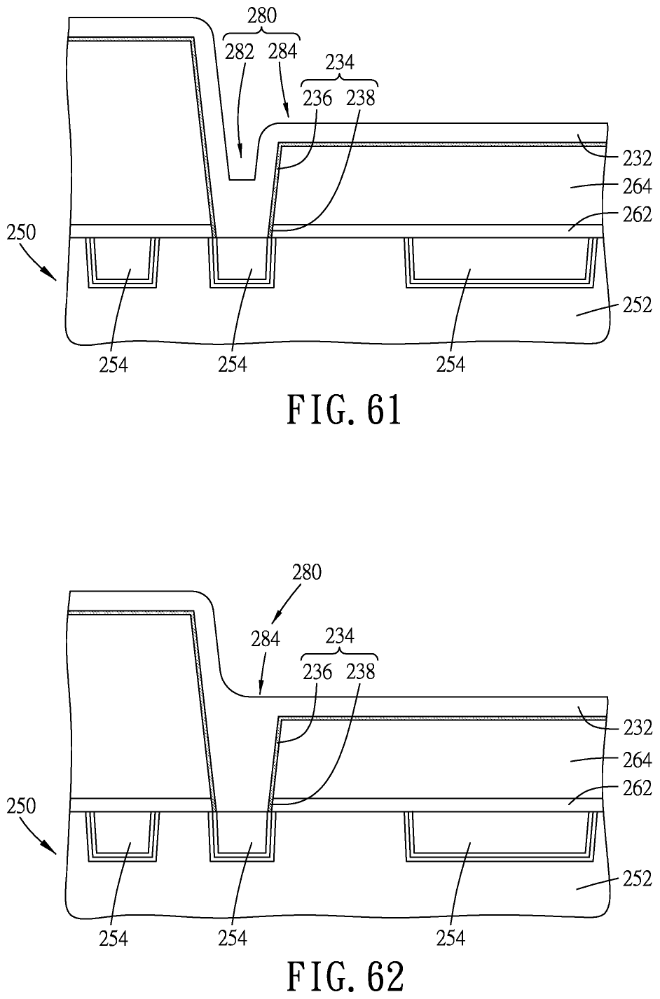

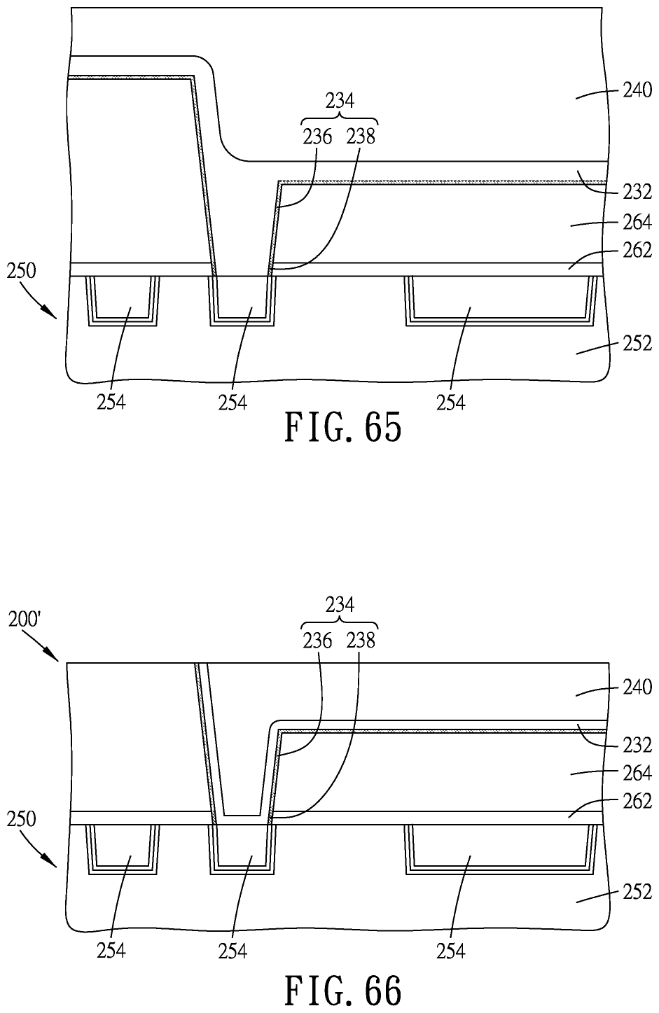

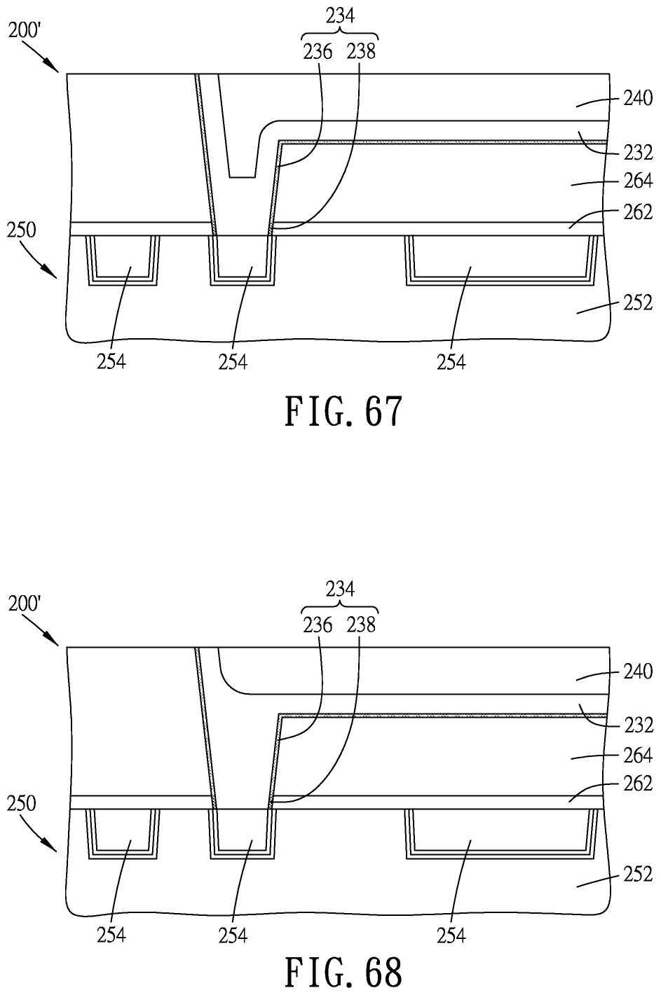

FIG. 55 illustrates a method 400 for forming a semiconductor device 200″ (see FIGS. 66 to 68) in accordance with some embodiments. FIGS. 56 to 68 are schematic views showing intermediate stages of the method 400 as depicted in FIG. 55. Additional steps which are not limited to those described in the method 400, can be provided before, during or after forming the semiconductor device 200″, and some of the steps described herein may be replaced by other steps or be eliminated. Similarly, additional features may be present, and/or features present may be replaced or eliminated in additional embodiments.

Referring to FIG. 55, in a step 402 of the method 400, the conductive feature is formed. Referring to FIG. 56, in some embodiments, the conductive feature 250 may include a structure that is the same or similar to the structure of the conductive feature 250 shown in FIGS. 15 to 17 with any necessary changes made to the conductive feature 250 in FIG. 56. In some embodiments, the structure below the conductive feature 250 in FIGS. 15 to 17 may be applied to the conductive feature 250 (e.g., may be disposed below the conductive feature 250), but is not shown in FIG. 56 and subsequent steps, for the sake of brevity.

Referring to FIG. 55, in a step 404 of the method 400, the first dielectric feature is formed. Referring to FIG. 56, in some embodiments, the first dielectric feature 264 is formed over the conductive feature 250. In some embodiments, prior to forming the first dielectric feature 264, the first ESL 262 may be formed over the conductive feature 250.

Referring to FIG. 55, in a step 406 of the method 400, a trench structure is formed. Referring to FIG. 56, in some embodiments, the trench structure 280 may be formed in the first dielectric feature 264, and penetrates the first dielectric feature 264 and the first ESL 262 to expose a corresponding one of the conductive structures 254. In some embodiments, the trench structure 280 may include a first trench portion 282, and a second trench portion 284 that is wider than the first trench portion 282. That is, the trench structure 280 may be used for a dual-damascene process. In some embodiments, the trench structure 280 may be formed by dry etching (e.g., plasma dry etching), other suitable techniques, or any combination thereof. In some embodiments, the first trench portion 282 of the trench structure 280 may have a width (W3) ranging from about 1 nm to about 250 nm, but other ranges of values are also within the scope of this disclosure. In some embodiments, if the width (W3) of the first trench portion 282 of the trench structure 280 is too small, such as smaller than about 1 nm, it may be difficult to fill the first trench portion 282 of the trench structure 280 in subsequent processes. In some embodiments, if the width (W3) of the first trench portion 282 of the trench structure 280 is too large, such as larger than about 250 nm, the first trench portion 282 of the trench structure 280 may occupy a large area. The width of the second trench portion 284 of the trench structure 280 may be determined by the width (W3) of the first trench portion 282 (e.g., may be greater than the width (W3) of the first trench portion 282).

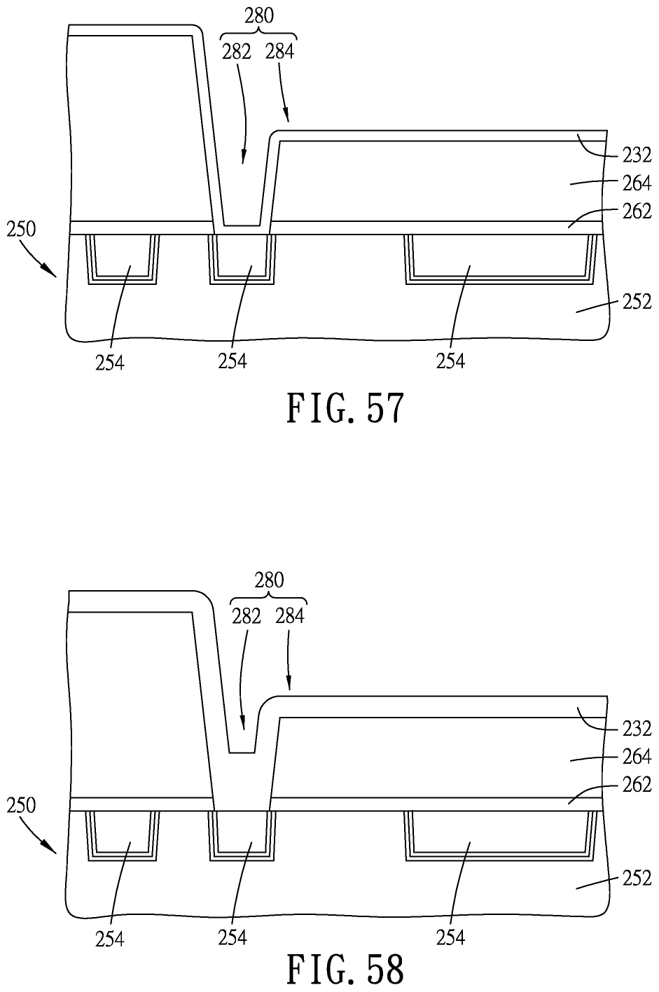

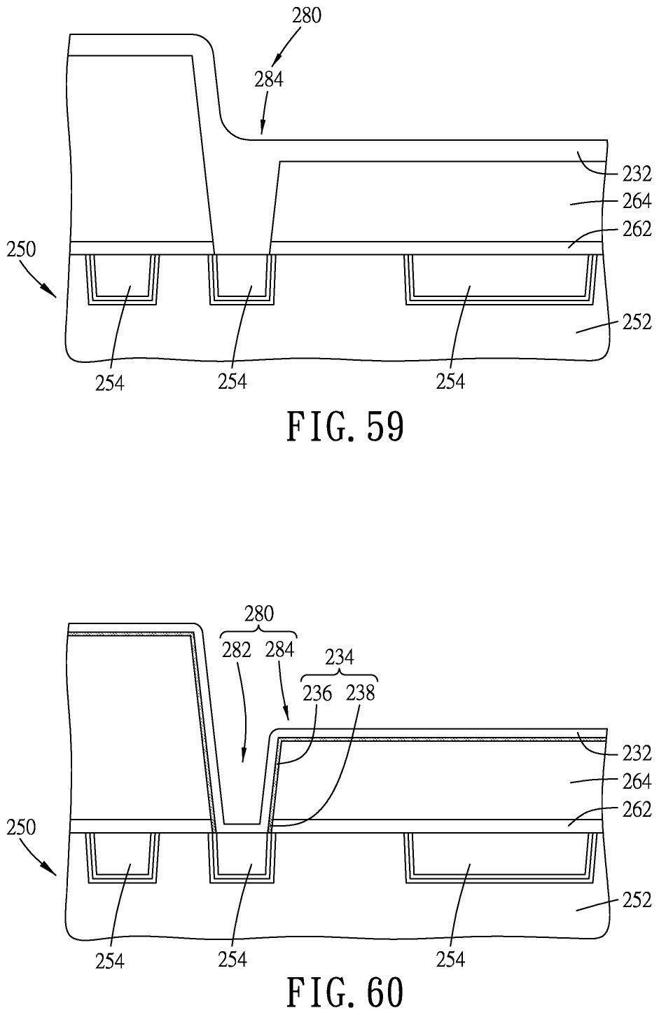

Referring to FIG. 55, in a step 408 of the method 400, the conductive element is formed. Referring to FIGS. 57 to 59, in some embodiments, the conductive element 232 as illustrated in FIGS. 4 to 6 and the related description above is formed over the first dielectric feature 264 and in the trench structure 280. Referring to FIG. 57, in some embodiments, the conductive element 232 may be formed in a conformal manner (e.g., by ALD, CVD, other suitable techniques, or any combination thereof) on the first dielectric feature 264 and partially filling the first and second trench portions 282, 284 of the trench structure 280. Referring to FIG. 58, in some embodiments, the conductive element 232 may be formed in a non-conformal manner (e.g., by CVD, PVD, other suitable techniques, or any combination thereof) on the first dielectric feature 264 and partially filling the first and second trench portions 282, 284 of the trench structure 280, where the thickness of the conductive element 232 on the bottom wall of the first trench portion 282 of the trench structure 280 is thicker, and the thickness of the conductive element 232 over the first dielectric feature 264 is thinner. Referring to FIG. 59, in some embodiments, the conductive element 232 may be formed to completely fill the first trench portion 282 of the trench structure 280 (see FIG. 56) and partially fill the second trench portion 284 of the trench structure 280.

Referring to FIG. 55, in a step 410 of the method 400, the barrier feature is formed. Referring to FIGS. 60 to 62, in some embodiments, the barrier feature 234 is formed by reaction between the conductive element 232 and the first dielectric feature 264 and the first ESL 262, where the formation mechanism of the barrier feature 234 shown in FIGS. 60 to 62 are similar to the formation mechanism of the barrier feature 234 shown in FIGS. 7 to 9, and are therefore not repeated for the sake of brevity. In some embodiments, the barrier feature 234 includes the first barrier layer 236 as a result of reaction between the conductive element 232 and the first dielectric feature 264, and the second barrier layer 238 as a result of reaction between the conductive element 232 and the first ESL 262.

Referring to FIGS. 60 to 65, in some embodiments, the filling contact material 240 may be formed over the conductive element 232 and fills the first and second trench portions 282, 284 of the trench structure 280.

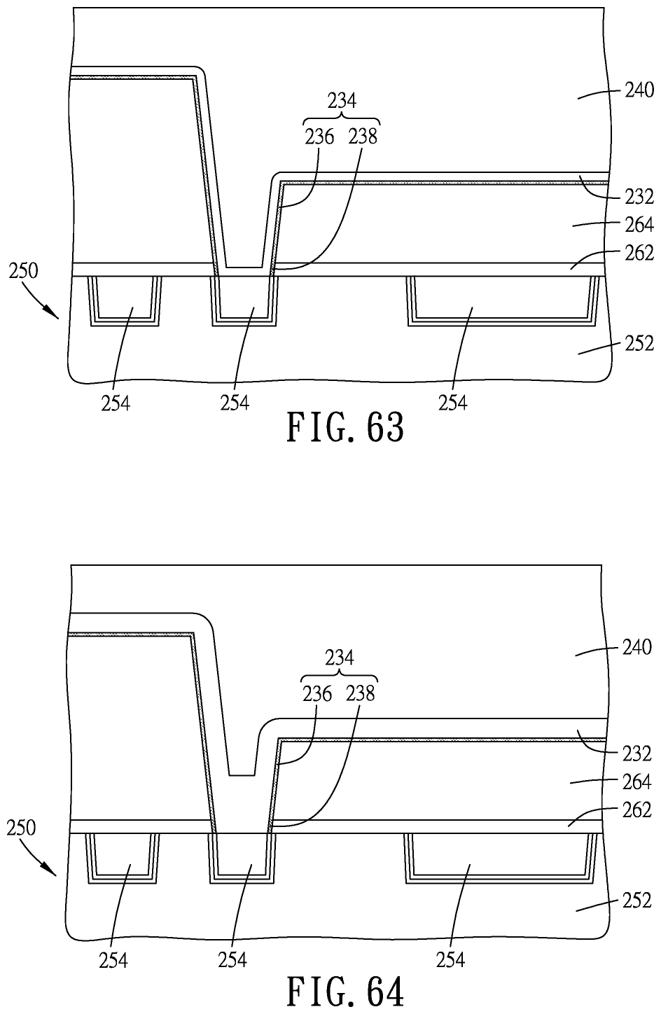

Referring to FIG. 55, in a step 412 of the method 300, a portion of the conductive element is removed. Referring to FIGS. 63 to 68, in some embodiments, portions of the conductive element 232, the barrier feature 234, and the filling contact material 240 may be removed, so that the trench structure (see FIG. 56) is filled with a portion of the filling contact material 240, a portion of the conductive element 232 surrounding the filling contact material 240, and a portion of the barrier feature 234 surrounding the conductive element 232, thereby obtaining the semiconductor device 200″.

The embodiments of the present disclosure have some advantageous features. Since the barrier feature 234 of this disclosure is formed by the reaction between the conductive element 232 and the dielectric layer 209 (or the first dielectric feature 264), the barrier feature 234 would not occupy a large amount of space in the contact opening feature 224, the via hole 266, or the trench structure 280. In contrast, if a barrier layer was deposited in the contact opening feature 224, the via hole 266, or the trench structure 280, such a barrier layer would occupy more space and would leave less space available for subsequently formed metal, leading to higher resistance since the volume of the subsequently formed metal will be smaller. In addition, since the barrier feature 234 of this disclosure is formed by reaction between a metal alloy and a dielectric layer, an interface between the metal alloy and a conductive structure (e.g., the interface between the conductive element 232 and the contact structures 216/gate structures 210 (see FIGS. 12 to 14), and the interface between the conductive element 232 and the conductive structures 254 (see FIGS. 28 to 30 and 66 to 68)) is not formed with the barrier feature 234, thereby reducing resistance at such interface. Moreover, this disclosure also provides a hybrid conductive structure, such as the first, second and third contact structures 244, 246, 248 shown in FIGS. 12 and 13, where each of the first, second and third contact structures 244, 246, 248 includes the conductive element 232 and the filling contact material 240, where the conductive element 232 may be made of a material that can react with the dielectric layer 209 (see FIG. 2) and the filling contact material 240 may be made of a material that has superior conductivity, desirable electromigration property, and/or other suitable properties, and where the first metal of the conductive element 232 may include a metal that has superior conductivity and the second metal of the conductive element 232 may include a metal that is more reactive with the dielectric layer 209.

In accordance with some embodiments of the present disclosure, a semiconductor device includes a dielectric structure, a conductive structure, a first dielectric feature, a conductive element, and a barrier feature. The conductive structure is disposed in the dielectric structure. The first dielectric feature is disposed over the dielectric structure. The conductive element is disposed in the first dielectric feature and is connected to the conductive structure. The barrier feature is disposed around the conductive element and is disposed outside of the conductive structure.

In accordance with some embodiments of the present disclosure, the conductive element includes a first metal, and a second metal different from the first metal and is distributed in the first metal. The barrier feature includes silicide or oxide of the second metal.

In accordance with some embodiments of the present disclosure, the first metal includes Cu, Ag, Au, Ni, Co, Fe, Ru, Os, Re, Ir, Pt, Pd, Rh, Al, W, Mo, or a transition metal. The second metal includes Al, Mn, Ti, Zr, Hf, Nb, Ta, Mo, W, Zn, V, Cr, Sc, Fe, or Y.

In accordance with some embodiments of the present disclosure, the semiconductor device further includes a filling contact material. The conductive element is disposed around the filling contact material.

In accordance with some embodiments of the present disclosure, the semiconductor device further includes an etching stop layer that is disposed between the dielectric structure and the first dielectric feature. The barrier feature includes a first barrier layer that is in contact with the first dielectric feature, and a second barrier layer that is different from the first barrier layer and that is in contact with the etching stop layer.

In accordance with some embodiments of the present disclosure, the semiconductor device further includes a second dielectric feature, a conductive layer, and a barrier element. The second dielectric feature is disposed over the first dielectric feature. The conductive layer is disposed in the second dielectric feature and is connected to the conductive element. The barrier element is disposed around the conductive layer and is disposed outside of the conductive element.

In accordance with some embodiments of the present disclosure, a semiconductor device includes a substrate, two source/drain regions, a dielectric layer, at least one contact structure, a gate structure, and a contact feature. The source/drain regions are disposed in the substrate, and are separated from each other. The dielectric layer is disposed over the substrate. The at least one contact structure is disposed in the dielectric layer and is connected to one of the source/drain regions. The gate structure is disposed in the dielectric layer and is located over and between the source/drain regions. The contact feature is disposed in the dielectric layer, and is connected to the at least one contact structure and the gate structure. The contact feature includes a conductive element, and a barrier feature disposed around the conductive element and disposed outside of the at least one contact structure and the gate structure.

In accordance with some embodiments of the present disclosure, the conductive element includes a first metal and a second metal different from the first metal and distributed in the first metal. The second metal includes Al, Mn, Ti, Zr, Hf, Nb, Ta, Mo, W, Zn, V, Cr, Sc, Fe, or Y. The barrier feature includes silicide or oxide of Al, Mn, Ti, Zr, Hf, Nb, Ta, Mo, W, Zn, V, Cr, Sc, Fe, or Y.

In accordance with some embodiments of the present disclosure, the first metal includes Cu, Ag, Au, Ni, Co, Fe, Ru, Os, Re, Ir, Pt, Pd, Rh, Al, W, Mo, or a transition metal.

In accordance with some embodiments of the present disclosure, the contact feature further includes a filling contact material. The conductive element is disposed around the filling contact material.

In accordance with some embodiments of the present disclosure, the semiconductor device further includes a contact etching stop layer disposed in the dielectric layer. The barrier feature includes a first barrier layer that is in contact with the dielectric layer, and a second barrier layer that is different from the first barrier layer and that is in contact with the contact etching stop layer.

In accordance with some embodiments of the present disclosure, a method includes: forming a conductive feature including a dielectric structure and a conductive structure disposed in the dielectric structure; forming a first dielectric feature over the conductive feature; forming a trench structure in the first dielectric feature to expose the conductive structure; forming a conductive element in the trench structure to be connected to the conductive structure, the conductive element including a first metal and a second metal different from the first metal and distributed in the first metal; and reacting the second metal of the conductive element with the first dielectric feature to form a barrier feature.

In accordance with some embodiments of the present disclosure, in the step of reacting the second metal of the conductive element with the first dielectric feature, the barrier feature is formed to include silicide or oxide of the second metal.

In accordance with some embodiments of the present disclosure, the method further includes forming a filling contact material over the conductive element to completely fill the trench structure.

In accordance with some embodiments of the present disclosure, the method further includes: forming a second dielectric feature over the first dielectric feature; forming a trench in the second dielectric feature to expose the conductive element; forming a barrier element in the trench; and filling the trench with a conductive layer.

In accordance with some embodiments of the present disclosure, the method further includes selectively forming a blocking layer covering the conductive element, the barrier element being formed outside of the blocking layer and the conductive element.

In accordance with some embodiments of the present disclosure, in the step of forming the barrier element, the barrier element covers the conductive element.

In accordance with some embodiments of the present disclosure, in the step of forming the trench structure, the trench structure includes a first trench portion and a second trench portion that is disposed over and connected to the first trench portion and that is wider than the first trench portion.

In accordance with some embodiments of the present disclosure, in the step of forming the conductive element, the conductive element partially fills the first and second trench portions. The method further includes forming a filling contact material to completely fill the first and second trench portions.

In accordance with some embodiments of the present disclosure, in the step of forming the conductive element, the conductive element completely fills the first trench portion and partially fills the second trench portion. The method further includes forming a filling contact material to completely fill the second trench portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a dielectric structure;
a conductive structure disposed in the dielectric structure;
a first dielectric feature disposed over the dielectric structure;
a conductive element disposed in the first dielectric feature and connected to the conductive structure; and
a barrier feature disposed around the conductive element and disposed outside of the conductive structure.

2. The semiconductor device as claimed in claim 1, wherein the conductive element includes a first metal and a second metal different from the first metal and distributed in the first metal, and the barrier feature includes silicide or oxide of the second metal.

3. The semiconductor device as claimed in claim 2, wherein the first metal includes Cu, Ag, Au, Ni, Co, Fe, Ru, Os, Re, Ir, Pt, Pd, Rh, Al, W, Mo, or a transition metal, and the second metal includes Al, Mn, Ti, Zr, Hf, Nb, Ta, Mo, W, Zn, V, Cr, Sc, Fe, or Y.

4. The semiconductor device as claimed in claim 1, further comprising a filling contact material, the conductive element being disposed around the filling contact material.

5. The semiconductor device as claimed in claim 1, further comprising an etching stop layer that is disposed between the dielectric structure and the first dielectric feature, the barrier feature including a first barrier layer that is in contact with the first dielectric feature and a second barrier layer that is different from the first barrier layer and that is in contact with the etching stop layer.

6. The semiconductor device as claimed in claim 1, further comprising:
a second dielectric feature that is disposed over the first dielectric feature;
a conductive layer that is disposed in the second dielectric feature and that is connected to the conductive element; and
a barrier element that is disposed around the conductive layer and that is disposed outside of the conductive element.

7. A semiconductor device comprising:
a substrate;
two source/drain regions disposed in the substrate and separated from each other;
a dielectric layer disposed over the substrate;
at least one contact structure disposed in the dielectric layer and connected to one of the source/drain regions;
a gate structure disposed in the dielectric layer and located over and between the source/drain regions; and
a contact feature disposed in the dielectric layer and connected to the at least one contact structure and the gate structure, the contact feature including a conductive element, and a barrier feature disposed around the conductive element and disposed outside of the at least one contact structure and the gate structure.

8. The semiconductor device as claimed in claim 7, wherein:
the conductive element includes a first metal and a second metal different from the first metal and distributed in the first metal;
the second metal includes Al, Mn, Ti, Zr, Hf, Nb, Ta, Mo, W, Zn, V, Cr, Sc, Fe, or Y; and
the barrier feature includes silicide or oxide of Al, Mn, Ti, Zr, Hf, Nb, Ta, Mo, W, Zn, V, Cr, Sc, Fe, or Y.

9. The semiconductor device as claimed in claim 8, wherein the first metal includes Cu, Ag, Au, Ni, Co, Fe, Ru, Os, Re, Ir, Pt, Pd, Rh, Al, W, Mo, or a transition metal.

10. The semiconductor device as claimed in claim 7, wherein the contact feature further includes a filling contact material, and the conductive element is disposed around the filling contact material.

11. The semiconductor device as claimed in claim 7, further comprising a contact etching stop layer disposed in the dielectric layer, the barrier feature including a first barrier layer that is in contact with the dielectric layer and a second barrier layer that is different from the first barrier layer and that is in contact with the contact etching stop layer.

12. A method for forming a semiconductor device comprising:
forming a conductive feature including a dielectric structure and a conductive structure disposed in the dielectric structure;
forming a first dielectric feature over the conductive feature;
forming a trench structure in the first dielectric feature to expose the conductive structure;
forming a conductive element in the trench structure to be connected to the conductive structure, the conductive element including a first metal and a second metal different from the first metal and distributed in the first metal; and
reacting the second metal of the conductive element with the first dielectric feature to form a barrier feature.

13. The method as claimed in claim 12, wherein, in the step of reacting the second metal of the conductive element with the first dielectric feature, the barrier feature is formed to include silicide or oxide of the second metal.

14. The method as claimed in claim 12, further comprising forming a filling contact material over the conductive element to completely fill the trench structure.

15. The method as claimed in claim 12, further comprising:
forming a second dielectric feature over the first dielectric feature;
forming a trench in the second dielectric feature to expose the conductive element;
forming a barrier element in the trench; and
filling the trench with a conductive layer.

16. The method as claimed in claim 15, further comprising selectively forming a blocking layer covering the conductive element, the barrier element being formed outside of the blocking layer and the conductive element.

17. The method as claimed in claim 15, wherein, in the step of forming the barrier element, the barrier element covers the conductive element.

18. The method as claimed in claim 12, wherein, in the step of forming the trench structure, the trench structure includes a first trench portion and a second trench portion that is disposed over and connected to the first trench portion and that is wider than the first trench portion.

19. The method as claimed in claim 18, wherein:
in the step of forming the conductive element, the conductive element partially fills the first and second trench portions; and
the method further comprises forming a filling contact material to completely fill the first and second trench portions.

20. The method as claimed in claim 18, wherein:
in the step of forming the conductive element, the conductive element completely fills the first trench portion and partially fills the second trench portion; and
the method further comprises forming a filling contact material to completely fill the second trench portion.
